(19) United States
(12) Patent Application Publication
(10) Pub. No.: US 2025/0324648 A1
(43) Pub. Date: Oct. 16, 2025

(54) SEMICONDUCTOR DEVICE

(71) Applicant: SAMSUNG ELECTRONICS CO., LTD., Suwon-si (KR)

(72) Inventors: Jeong Hyeon LEE, Suwon-si (KR); Yeong Han GWON, Suwon-si (KR); Han Young SONG, Suwon-si (KR); Jun Youp LEE, Suwon-si (KR); Hak Jong LEE, Suwon-si (KR)

(73) Assignee: SAMSUNG ELECTRONICS CO., LTD., Suwon-si (KR)

(21) Appl. No.: 18/987,817

(22) Filed: Dec. 19, 2024

(30) Foreign Application Priority Data
Apr. 15, 2024 (KR) 10-2024-0049995

(51) Int. Cl. H10D 30/00; H10D 30/01

(52) U.S. Cl. CPC H10D 30/502; H10D 30/0191; H10D 30/0198

(57) ABSTRACT

A semiconductor device, including: a lower interlayer insulating layer; an insulating pattern extending in a first horizontal direction on an upper surface of the lower interlayer insulating layer; a plurality of nanosheets on the insulating pattern and spaced apart in a vertical direction; an active cut including a first portion penetrating the lower interlayer insulating layer and the insulating pattern in the vertical direction, and a second portion separating the plurality of nanosheets in the first horizontal direction on an upper surface of the first portion, wherein a lower surface of the second portion is on an upper surface of the insulating pattern, and wherein the second portion is on inner sidewalls of the plurality of nanosheets in the first horizontal direction; a first source/drain region on a first side of the active cut on the insulating pattern, wherein the first source/drain region is on first outer sidewalls of the plurality of nanosheets; a second source/drain region on a second side of the active cut opposite to the first side of the active cut in the first horizontal direction on the insulating pattern, wherein the second source/drain region is on second outer sidewalls of the plurality of nanosheets; and a bottom source/drain contact penetrating the lower interlayer insulating layer and the insulating pattern in the vertical direction, wherein the bottom source/drain contact is electrically connected to the second source/drain region, and wherein the bottom source/drain contact overlaps the first portion of the active cut in the first horizontal direction, wherein a width of the upper surface of the first portion of the active cut in the first horizontal direction is smaller than a width of a lower surface of the first portion of the active cut in the first horizontal direction.

### CROSS-REFERENCE TO RELATED APPLICATION

This application is based on and claims priority under 35 U.S.C. § 119 to Korean Patent Application No. 10-2024-0049995 filed on Apr. 15, 2024 in the Korean Intellectual Property Office, the disclosure of which is incorporated by reference herein in its entirety.

### BACKGROUND

### 1. Technical Field

The disclosure relates to a semiconductor device, and more particularly, to a semiconductor device including a multi-bridge channel field-effect transistor (MBCFET™).

### 2. Description of the Related Art

As a scaling technique for increasing the density of integrated circuit devices, the concept of a multi-gate transistor has been proposed in which a silicon body in the form of a fin or nanowire is formed on a substrate and a gate is formed on the surface of the silicon body.

The multi-gate transistor takes advantage of its three-dimensional (3D) channel, allowing for easy scaling both up and down. Additionally, the multi-gate transistor offers improved control over the current without the need to increase the gate length. Furthermore, the multi-gate transistor effectively mitigates the short channel effect (SCE), which is the phenomenon where the electric potential of a channel region is affected by the drain voltage.

### SUMMARY

Provided is a semiconductor device designed to have an active cut formed from the backside, which may reduce the complexity of the formation of the active cut and prevent the etching of source/drain regions during the formation of the active cut.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

In accordance with an aspect of the disclosure, a semiconductor device includes: a lower interlayer insulating layer; an insulating pattern extending in a first horizontal direction on an upper surface of the lower interlayer insulating layer; a plurality of nanosheets on the insulating pattern and spaced apart in a vertical direction; an active cut including a first portion penetrating the lower interlayer insulating layer and the insulating pattern in the vertical direction, and a second portion separating the plurality of nanosheets in the first horizontal direction on an upper surface of the first portion, wherein a lower surface of the second portion is on an upper surface of the insulating pattern, and wherein the second portion is on inner sidewalls of the plurality of nanosheets in the first horizontal direction; a first source/drain region on a first side of the active cut on the insulating pattern, wherein the first source/drain region is on first outer sidewalls of the plurality of nanosheets; a second source/drain region on a second side of the active cut opposite to the first side of the active cut in the first horizontal direction on the insulating pattern, wherein the second source/drain region is on second outer sidewalls of the plurality of nanosheets; and a bottom source/drain contact penetrating the lower interlayer insulating layer and the insulating pattern in the vertical direction, wherein the bottom source/drain contact is electrically connected to the second source/drain region, and wherein the bottom source/drain contact overlaps the first portion of the active cut in the first horizontal direction, wherein a width of the upper surface of the first portion of the active cut in the first horizontal direction is smaller than a width of a lower surface of the first portion of the active cut in the first horizontal direction.

In accordance with an aspect of the disclosure, a semiconductor device includes: a lower interlayer insulating layer; an insulating pattern extending in a first horizontal direction on an upper surface of the lower interlayer insulating layer; a first gate electrode extending in a second horizontal direction on the insulating pattern, wherein the second horizontal direction is different from the first horizontal direction; a second gate electrode extending in the second horizontal direction on the insulating pattern, wherein the second gate electrode is spaced apart from the first gate electrode in the first horizontal direction; an active cut including a first portion penetrating the lower interlayer insulating layer and the insulating pattern in a vertical direction, and a second portion on an upper surface of the first portion, wherein a lower surface of the second portion is on an upper surface of the insulating pattern; a liner layer between the first portion of the active cut and each of the lower interlayer insulating layer and the insulating pattern, wherein the liner layer being is on both sidewalls of the first portion of the active cut in the first horizontal direction; a first capping pattern on an upper surface of the first gate electrode, wherein the first capping pattern extends in the second horizontal direction; a second capping pattern on an upper surface of the second gate electrode, wherein the second capping pattern extends in the second horizontal direction; and a third capping pattern on an upper surface of the second portion of the active cut, wherein the third capping pattern extends in the second horizontal direction, wherein upper surfaces of the first capping pattern, the second capping pattern, and the third capping pattern are on a same plane, wherein the upper surface of the second portion of the active cut is lower than the upper surface of the third capping pattern, and wherein a width of the upper surface of the first portion of the active cut in the first horizontal direction is smaller than a width of a lower surface of the first portion of the active cut in the first horizontal direction.

In accordance with an aspect of the disclosure, a semiconductor device includes: a lower interlayer insulating layer; an insulating pattern extending in a first horizontal direction on an upper surface of the lower interlayer insulating layer; a plurality of nanosheets on the insulating pattern and spaced apart in a vertical direction; a first gate electrode extending in a second horizontal direction on the insulating pattern, wherein the second horizontal direction is different from the first horizontal direction; a second gate electrode extending in the second horizontal direction on the insulating pattern, wherein the second gate electrode is spaced apart from the first gate electrode in the first horizontal direction; an active cut extending in the second horizontal direction between the first and second gate electrodes, wherein the active cut includes a first portion penetrating the lower interlayer insulating layer and the insulating pattern in the vertical direction, and a second portion separating the plurality of nanosheets in the first horizontal direction on an upper surface of the first portion, wherein a lower surface of the second portion is on an upper surface of the insulating pattern, and wherein the second portion is on inner sidewalls of the plurality of nanosheets in the first horizontal direction; a first source/drain region between the first gate electrode and the active cut, on the insulating pattern, wherein the first source/drain region is on first outer sidewalls of the plurality of nanosheets; a second source/drain region between the active cut and the second gate electrode on the insulating pattern, wherein the second source/drain region is on second outer sidewalls of the plurality of nanosheets; a liner layer between the first portion of the active cut and each of the lower interlayer insulating layer and the insulating pattern, wherein the liner layer is on both sidewalls of the first portion of the active cut in the first horizontal direction; a capping pattern on an upper surface of the second portion of the active cut, wherein the capping pattern extends in the second horizontal direction; a gate spacer on both sidewalls of the second portion of the active cut in the first horizontal direction on an upper surface of an uppermost nanosheet of the plurality of nanosheets, wherein the gate spacer is on the second portion of the active cut; and a bottom source/drain contact penetrating the lower interlayer insulating layer and the insulating pattern in the vertical direction, wherein the bottom source/drain contact is electrically connected to the second source/drain region, and wherein the bottom source/drain contact overlaps the first portion of the active cut in the first horizontal direction, wherein the upper surface of the second portion of the active cut is lower than an upper surface of the capping pattern, wherein at least some of the second portion of the active cut overlaps the plurality of nanosheets in the vertical direction between adjacent nanosheets from among the plurality of nanosheets, and wherein a width of the upper surface of the first portion of the active cut in the first horizontal direction is smaller than a width of a lower surface of the first portion of the active cut in the first horizontal direction.

It should be noted that the effects of the present disclosure are not limited to those described above, and other effects of the present disclosure will be apparent from the following description.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a layout view of a semiconductor device according to an embodiment;

FIG. 2 is a cross-sectional view taken along line A-A′ of FIG. 1, according to an embodiment;

FIG. 3 is a cross-sectional view taken along line B-B′ of FIG. 1, according to an embodiment;

FIG. 4 is a cross-sectional view taken along line C-C′ of FIG. 1, according to an embodiment;

FIGS. 5 through 36 are cross-sectional views for explaining intermediate steps of a method of fabricating a semiconductor device according to embodiments;

FIG. 37 is a cross-sectional view for explaining a semiconductor device according to an embodiment;

FIG. 38 is a cross-sectional view for explaining a semiconductor device according to an embodiment;

FIG. 39 is a cross-sectional view for explaining a semiconductor device according to an embodiment; and

FIG. 40 is a cross-sectional view for explaining a semiconductor device according to an embodiment.

### DETAILED DESCRIPTION

Semiconductor devices according to some embodiments of the present disclosure are illustrated in the accompanying drawings as including multi-bridge channel field-effect transistors (MBCFETs™) with nanosheets, but embodiments are not limited thereto. In some embodiments, the semiconductor devices according to some embodiments of the present disclosure may include fin-type field-effect transistors (FinFETs) with fin-shaped pattern channel regions, tunneling field-effect transistors (FETs), or three-dimensional (3D) transistors. Furthermore, the semiconductor devices according to some embodiments of the present disclosure may include bipolar junction transistors or lateral double-diffused metal-oxide semiconductor (LDMOS) transistors.

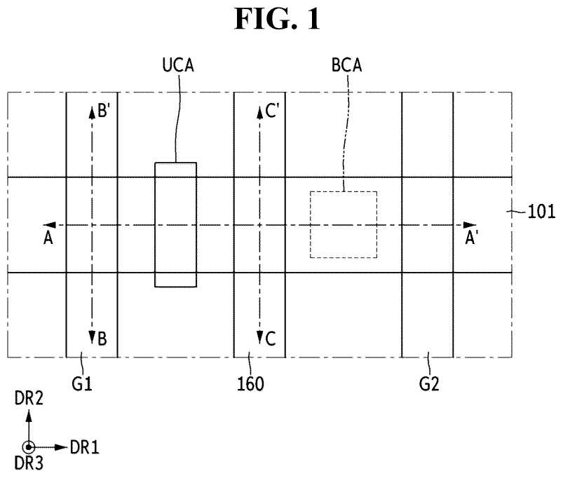

A semiconductor device according to some embodiments of the present disclosure is described below with reference to FIGS. 1 through 4.

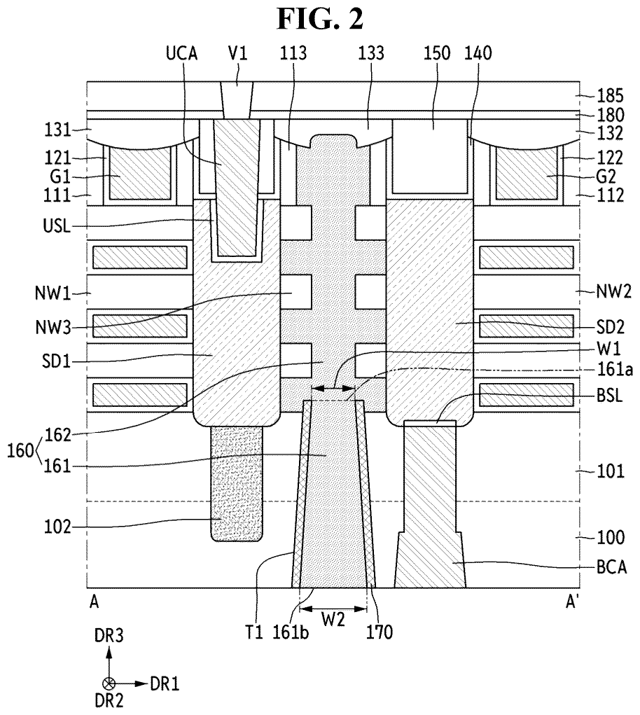

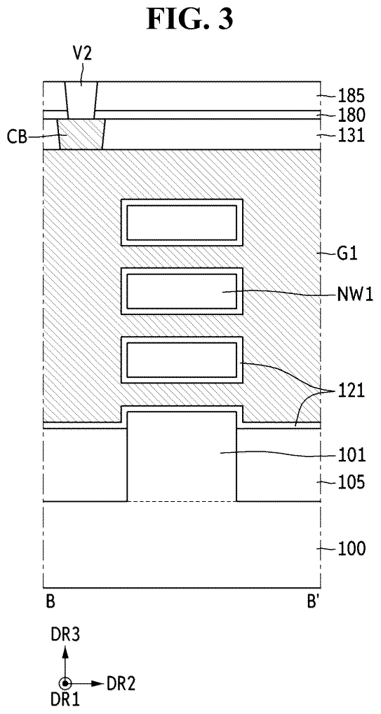

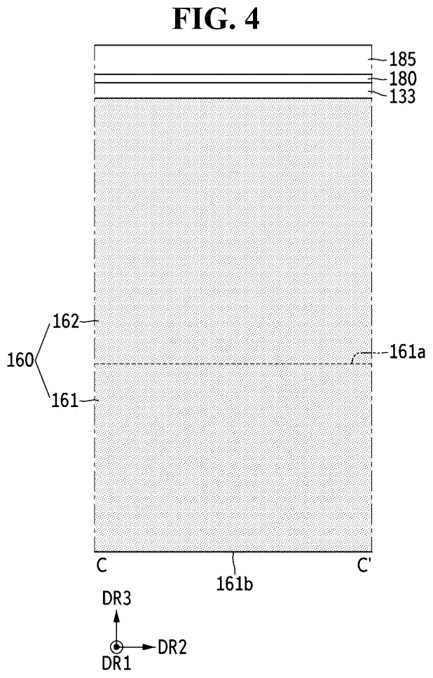

FIG. 1 is a layout view for explaining a semiconductor device according to some embodiments of the present disclosure. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1.

Referring to FIGS. 1 through 4, the semiconductor device according to some embodiments of the present disclosure includes a lower interlayer insulating layer 100, an insulating pattern 101, a first sacrificial pattern 102, a field insulating layer 105, a first plurality of nanosheets NW1, a second plurality of nanosheets NW2, a third plurality of nanosheets NW3, a first gate electrode G1, a second gate electrode G2, a first gate spacer 111, a second gate spacer 112, a third gate spacer 113, a first gate insulating layer 121, a second gate insulating layer 122, a first capping pattern 131, a second capping pattern 132, a third capping pattern 133, a first source/drain region SD1, a second source/drain region SD2, a first etching stop layer 140, a first upper interlayer insulating layer 150, an active cut 160, a liner layer 170, a gate contact CB, an upper source/drain contact UCA, a bottom source/drain contact BCA, an upper silicide layer USL, a lower silicide layer BSL, a second etching stop layer 180, a second upper interlayer insulating layer 185, a first via V1, and a second via V2.

The lower interlayer insulating layer 100 may include, for example, at least one of silicon oxide, silicon nitride, silicon oxynitride, and a low-k material. The low-k material may be, for example, Fluorinated Tetraethyl Orthosilicate (FTEOS), Hydrogen Silsesquioxane (HSQ), Bis-benzocyclobutene (BCB), Tetramethyl Orthosilicate (TMOS), Octamethylcyclotetrasiloxane (OMCTS), Hexamethyldisiloxane (HMDS), Trimethylsilyl Borate (TMSB), Diacetoxyditertiarybutoxysiloxane (DADBS), Trimethylsilyl Phosphate (TMSP), Polytetrafluoroethylene (PTFE), Tonen Silazen (TOSZ), Fluoride Silicate Glass (FSG), polyimide nanofoam such as polypropylene oxide, Carbon Doped Silicon Oxide (CDO), Organo Silicate Glass (OSG), SiLK, Amorphous Fluorinated Carbon, silica aerogel, silica xerogel, mesoporous silica, or a combination thereof, but embodiments are not limited thereto.

In the description that follows, a first horizontal direction DR1 and a second horizontal direction DR2 may be defined as directions parallel to the upper surface of the lower interlayer insulating layer 100. The second horizontal direction DR2 may be defined as a different direction from the first horizontal direction DR1. A vertical direction DR3 may be defined as a direction perpendicular to both the first and second horizontal directions DR1 and DR2. For example, the vertical direction DR3 may be defined as a direction perpendicular to the upper surface of the lower interlayer insulating layer 100.

The insulating pattern 101 may extend in the first horizontal direction DR1 on the upper surface of the lower interlayer insulating layer 100. The insulating pattern 101 may protrude in the vertical direction DR3 from the upper surface of the lower interlayer insulating layer 100. The lower surface of the insulating pattern 101 may be in contact with the upper surface of the lower interlayer insulating layer 100. The insulating pattern 101 may include an insulating material. For example, the insulating pattern 101 may include the same material as the lower interlayer insulating layer 100.

The field insulating layer 105 may be disposed on the upper surface of the lower interlayer insulating layer 100. The field insulating layer 105 may surround the sidewalls of the insulating pattern 101. For example, the upper surface of the insulating pattern 101 may protrude in the vertical direction DR3 beyond the upper surface of the field insulating layer 105, but embodiments are not limited thereto. In some embodiments, the upper surface of the insulating pattern 101 may be formed on the same plane as the upper surface of the field insulating layer 105. The field insulating layer 105 may include, for example, an oxide film, a nitride film, an oxynitride film, or a combination thereof.

The first plurality of nanosheets NW1 may be disposed on the insulating pattern 101. The first plurality of nanosheets NW1 may be disposed at the intersection of the insulating pattern 101 and the first gate electrode G1. The second plurality of nanosheets NW2 may be disposed on the insulating pattern 101. The second plurality of nanosheets NW2 may be disposed at the intersection of the insulating pattern 101 and the second gate electrode G2. The second plurality of nanosheets NW2 may be spaced apart from the first plurality of nanosheets NW1 in the first horizontal direction DR1.

The third plurality of nanosheets NW3 may be disposed on the insulating pattern 101. The third plurality of nanosheets NW3 may be disposed at the intersection of the insulating pattern 101 and the active cut 160. The third plurality of nanosheets NW3 may be disposed between the first plurality of nanosheets NW1 and the second plurality of nanosheets NW2. The third plurality of nanosheets NW3 may be spaced apart from the first plurality of nanosheets NW1 in the first horizontal direction DR1. The second plurality of nanosheets NW2 may be spaced apart from the third plurality of nanosheets NW3 in the first horizontal direction DR1. For example, the third plurality of nanosheets NW3 may include first portions, and second portions that are spaced apart from the first portions in the first horizontal direction DR1. For example, the second portions of the third plurality of nanosheets NW3 may be spaced apart from the first portions of the third plurality of nanosheets NW3 in the first horizontal direction DR1.

The first plurality of nanosheets NW1, the second plurality of nanosheets NW2, and the third plurality of nanosheets NW3 may include stacks of multiple nanosheets that are vertically spaced apart in the vertical direction DR3. In FIGS. 2 and 3, the first plurality of nanosheets NW1, the second plurality of nanosheets NW2, and the third plurality of nanosheets NW3 are illustrated as including stacks of three nanosheets that are stacked in the vertical direction DR3 to be apart from one another, but embodiments are not limited thereto. In some embodiments, the first plurality of nanosheets NW1, the second plurality of nanosheets NW2, and the third plurality of nanosheets NW3 may include four or more stacks of nanosheets that are stacked in the vertical direction DR3 to be apart from one another. For example, the first plurality of nanosheets NW1, the second plurality of nanosheets NW2, and the third plurality of nanosheets NW3 may include silicon (Si), but embodiments are not limited thereto. In some embodiments, the first plurality of nanosheets NW1, the second plurality of nanosheets NW2, and the third plurality of nanosheets NW3 may include silicon-germanium (SiGe).

The first gate electrode G1 may extend in the second horizontal direction DR2 on the insulating pattern 101 and the field insulating layer 105. The first gate electrode G1 may surround the first plurality of nanosheets NW1. The second gate electrode G2 may extend in the second horizontal direction DR2 on the insulating pattern 101 and the field insulating layer 105. The second gate electrode G2 may surround the second plurality of nanosheets NW2. The second gate electrode G2 may be spaced apart from the first gate electrode G1 in the first horizontal direction DR1.

The first and second gate electrodes G1 and G2 may include, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. The first and second gate electrodes G1 and G2 may include a conductive metal oxide or conductive metal oxynitride, and may also include an oxidized form of any one of the aforementioned materials.

The first source/drain region SD1 may be disposed between the first plurality of nanosheets NW1 and the first outer sidewalls of the third plurality of nanosheets NW3, on the insulating pattern 101. For example, the first source/drain region SD1 may be in contact with the sidewalls, in the first horizontal direction DR1, of the first plurality of nanosheets NW1 and the first outer sidewalls, in the first horizontal direction DR1, of the third plurality of nanosheets NW3. The second source/drain region SD2 may be disposed between the second outer walls of the third plurality of nanosheets NW3 and the second plurality of nanosheets NW2, on the insulating pattern 101. The second outer sidewalls of the third plurality of nanosheets NW3 may be defined as the sidewalls of the third plurality of nanosheets NW3 that are opposite to the first outer sidewalls of the third plurality of nanosheets NW3 in the first horizontal direction DR1. For example, the second source/drain region SD2 may be in contact with the second outer sidewalls of the third plurality of nanosheets NW3 and the sidewalls, in the first horizontal direction DR1, of the second plurality of nanosheets NW2.

The first sacrificial pattern 102 may be disposed below the first source/drain region SD1. The first sacrificial pattern 102 may be in contact with the lower surface of the first source/drain region SD1. The first sacrificial pattern 102 may penetrate the insulating pattern 101 and the lower interlayer insulating layer 100 in the vertical direction DR3. For example, the lower interlayer insulating layer 100 may cover the lower surface of the first sacrificial pattern 102. For example, the sidewalls, in the first horizontal direction DR1, of the first sacrificial pattern 102 may be in contact with the insulating pattern 101 and the lower interlayer insulating layer 100. The first sacrificial pattern 102 may include a different material from the lower interlayer insulating layer 100 and the insulating pattern 101. For example, the first sacrificial pattern 102 may include SiGe.

For example, the first trench T1 may penetrate the lower interlayer insulating layer 100 and the insulating pattern 101 in the vertical direction DR3. For example, the first trench T1 may be formed below the third plurality of nanosheets NW3. For example, the upper surface of the first trench T1 may be formed higher than the upper surface of the insulating pattern 101. The sidewalls, in the first horizontal direction DR1, of the first trench T1 may have a continuous sloping profile in a direction toward the upper surface of the first trench T1. For example, the sidewalls, in the first horizontal direction DR1, of the first trench T1 may be not stepped.

The liner layer 170 may be disposed along the sidewalls of the first trench T1. For example, the liner layer 170 may be in contact with the lower interlayer insulating layer 100 and the insulating pattern 101. For example, the liner layer 170 may be conformally formed. For example, the upper surface of the liner layer 170 may be formed higher than the upper surface of the insulating pattern 101. For example, the lower surface of the liner layer 170 may be formed on the same plane as the lower surface of the lower interlayer insulating layer 100. However, embodiments are not limited thereto. In some embodiments, the lower interlayer insulating layer 100 may cover the lower surface of the liner layer 170. For example, the liner layer 170 may be spaced apart from the first sacrificial pattern 102 in the first horizontal direction DR1. For example, the liner layer 170 may include a different material from the lower interlayer insulating layer 100 and the insulating pattern 101. The liner layer 170 may include an insulating material. For example, the liner layer 170 may include at least one of silicon nitride (SiN), silicon oxynitride (SiON), silicon carbonitride (SiCN), silicon oxycarbonitride (SiOCN), silicon oxycarbide (SiOC), and a combination thereof, but embodiments are not limited thereto.

The active cut 160 may extend in the second horizontal direction DR2 between the first and second gate electrodes G1 and G2. For example, the active cut 160 may be disposed between the first and second source/drain regions SD1 and SD2. For example, the first source/drain region SD1 may be disposed on a first side of the active cut 160, and the second source/drain region SD2 may be disposed on a second side of the active cut 160, which is opposite to the first side of the active cut 160 in the first horizontal direction DR1. The active cut 160 may penetrate the lower interlayer insulating layer 100, the insulating pattern 101, and the third plurality of nanosheets NW3 in the vertical direction DR3. For example, the active cut 160 may separate the insulating pattern 101 in the first horizontal direction DR1. For example, the active cut 160 may separate the third plurality of nanosheets NW3 in the first horizontal direction DR1. For example, the active cut 160 may separate the third plurality of nanosheets NW3 into first portions and second portions. For example, the first portions of the third plurality of nanosheets NW3 may be in contact with the first source/drain region SD1, and the second portions of the third plurality of nanosheets NW3 may be in contact with the second portions of the third plurality of nanosheets NW3.

For example, the active cut 160 may include a first portion 161 and a second portion 162. The first portion 161 of the active cut 160 may be disposed between portions of the liner layer 170 within the first trench T1. For example, the first portion 161 of the active cut 160 may completely fill the interior of the first trench T1 along the sidewalls of the liner layer 170. The first portion 161 of the active cut 160 may penetrate both the lower interlayer insulating layer 100 and the insulating pattern 101 in the vertical direction DR3. For example, the sidewalls, in the first horizontal direction DR1, of the first portion 161 may be respectively spaced apart from the lower interlayer insulating layer 100 and the insulating pattern 101. For example, the liner layer 170 may be disposed between the first portion 161 of the active cut 160 and each of the lower interlayer insulating layer 100 and the insulating pattern 101.

For example, the sidewalls, in the first horizontal direction DR1, of the first portion 161 of the active cut 160 may be in contact with the liner layer 170. The first portion 161 of the active cut 160 may overlap with the first sacrificial pattern 102 in the first horizontal direction DR1. In some embodiments, the first portion 161 of the active cut 160 may be spaced apart from the first sacrificial pattern 102 in the first horizontal direction DR1. An upper surface 161a of the first portion 161 of the active cut 160 may be formed higher than the upper surface of the insulating pattern 101. For example, a lower surface 161b of the first portion 161 of the active cut 160 may be formed on the same plane as the lower surface of the lower interlayer insulating layer 100. However, embodiments are not limited thereto. In some embodiments, the lower interlayer insulating layer 100 may cover the lower surface 161b of the first portion 161 of the active cut 160.

For example, a width W1, in the first horizontal direction DR1, of the upper surface 161a of the first portion 161 of the active cut 160 may be smaller than a width W2, in the first horizontal direction DR1, of the lower surface 161b of the first portion 161. For example, the width, in the first horizontal direction DR1, of the first portion 161 may continuously decrease closer to the upper surface 161a of the first portion 161 of the active cut 160. For example, the sidewalls, in the first horizontal direction DR1, of the first portion 161 of the active cut 160 may have a continuous slope profile. For example, the sidewalls, in the first horizontal direction DR1, of the first portion 161 of the active cut 160 may not be stepped.

The second portion 162 of the active cut 160 may be disposed on the upper surface 161a of the first portion 161. For example, the second portion 162 of the active cut 160 may be in contact with the upper surface 161a of the first portion 161. For example, the second portion 162 of the active cut 160 may be in contact with the upper surface of the liner layer 170. For example, at least some of the second portion 162 of the active cut 160 may be in contact with the sidewalls, in the first horizontal direction DR1, of the liner layer 170. For example, the second portion 162 of the active cut 160 may separate the third plurality of nanosheets NW3 into first portions in contact with the first source/drain region SD1 and second portions in contact with the second source/drain region SD2. The second portion 162 of the active cut 160 may be in contact with both the inner sidewalls, in the first horizontal direction DR1, of the first portions of the third plurality of nanosheets NW3 and the inner sidewalls, in the first horizontal direction DR1, of the second portions of the third plurality of nanosheets NW3.

For example, the second portion 162 of the active cut 160 may surround the third plurality of nanosheets NW3. For example, between the upper surface of the insulating pattern 101 and the lower surface of the lowermost nanosheet of the third plurality of nanosheets NW3, at least some of the second portion 162 of the active cut 160 may overlap with the third plurality of nanosheets NW3 in the vertical direction DR3. Furthermore, between adjacent nanosheets from among the third plurality of nanosheets NW3, at least part of the second portion 162 of the active cut 160 may overlap with the third plurality of nanosheets NW3 in the vertical direction DR3. For example, the second portion 162 of the active cut 160 may be in contact with the upper and lower surfaces of each of the third plurality of nanosheets NW3. For example, at least some of the second portion 162 of the active cut 160 may overlap with the lower interlayer insulating layer 100 and the insulating pattern 101 in the vertical direction DR3.

For example, at least some of the first portion 161 of the active cut 160 may extend into the interior of the second portion 162 of the active cut 160. For example, at least some of the second portion 162 of the active cut 160 may overlap with the first portion 161 of the active cut 160 in the first horizontal direction DR1. For example, the lower surface 161b of the second portion 162 of the active cut 160 may be formed lower than the upper surface 161a of the first portion 161. The lower surface of the second portion 162 of the active cut 160 may be in contact with the upper surface of the insulating pattern 101. For example, between the upper surface of the insulating pattern 101 and the lower surface of the lowermost nanosheet of the third plurality of nanosheets NW3, the sidewalls, in the first horizontal direction DR1, of the second portion 162 of the active cut 160 may be in contact with both the first and second source/drain regions SD1 and SD2. Furthermore, between adjacent nanosheets from among the third plurality of nanosheets NW3, the sidewalls, in the first horizontal direction DR1, of the second portion 162 of the active cut 160 may be in contact with both the first and second source/drain regions SD1 and SD2.

For example, the second portion 162 of the active cut 160 may be integrally formed with the first portion 161 of the active cut 160. For example, the first and second portions 161 and 162 of the active cut 160 may include the same material. The active cut 160 may include an insulating material. For example, the active cut 160 may include at least one of SiN, SiON, SiCN, SiOCN, SiOC, and a combination thereof. However, embodiments are not limited thereto. For example, the active cut 160 may include a different material from the liner layer 170, but embodiments are not limited thereto. In some embodiments, the active cut 160 may include the same material as the liner layer 170.

The first gate spacer 111 may extend in the second horizontal direction DR2 along both sidewalls of the first gate electrode G1, on the upper surface of the uppermost nanosheet of the first plurality of nanosheets NW1 and the field insulating layer 105. The second gate spacer 112 may extend in the second horizontal direction DR2 along both sidewalls of the second gate electrode G2, on the upper surface of the uppermost nanosheet of the second plurality of nanosheets NW2 and the field insulating layer 105. The third gate spacer 113 may extend in the second horizontal direction DR2 along both sidewalls of the second portion 162 of the active cut 160, on the upper surface of the uppermost nanosheet of the third plurality of nanosheets NW3 and the field insulating layer 105. For example, the third gate spacer 113 may be in contact with the sidewalls, in the first horizontal direction DR1, of the second portion 162 of the active cut 160. The first gate spacer 111, the second gate spacer 112, and the third gate spacer 113 may include at least one of SiN, SiON, SiO₂, SiOCN, SiBN, SiOBN, SiOC, and a combination thereof, but embodiments are not limited thereto.

The first gate insulating layer 121 may be disposed between the first gate electrode G1 and the insulating pattern 101. The first gate insulating layer 121 may be disposed between the first gate electrode G1 and the field insulating layer 105. The first gate insulating layer 121 may be disposed between the first gate electrode G1 and the first gate spacer 111. The first gate insulating layer 121 may be disposed between the first gate electrode G1 and the first plurality of nanosheets NW1. The first gate insulating layer 121 may be disposed between the first gate electrode G1 and the first source/drain region SD1. For example, the first gate insulating layer 121 may contact the first source/drain region SD1.

The second gate insulating layer 122 may be disposed between the second gate electrode G2 and the insulating pattern 101. The second gate insulating layer 122 may be disposed between the second gate electrode G2 and the field insulating layer 105. The second gate insulating layer 122 may be disposed between the second gate electrode G2 and the second gate spacer 112. The second gate insulating layer 122 may be disposed between the second gate electrode G2 and the second plurality of nanosheets NW2. The second gate insulating layer 122 may be disposed between the second gate electrode G2 and the second source/drain region SD2. For example, the second gate insulating layer 122 may contact the second source/drain region SD2.

The first and second gate insulating layers 121 and 122 may include at least one of silicon oxide, silicon oxynitride, silicon nitride, and a high-k material with a greater dielectric constant than silicon oxide. The high-k material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The semiconductor device according to some embodiments of the present disclosure may include negative capacitance (NC) FETs using negative capacitors. For example, each of the first and second gate insulating layers 121 and 122 may include a ferroelectric material film having ferroelectric properties and a paraelectric material film having paraelectric properties.

The ferroelectric material film may have a negative capacitance, and the paraelectric material film may have a positive capacitance. For example, if two or more capacitors are connected in series and have positive capacitance, the total capacitance of the two or more capacitors may be lower than the capacitance of each of the two or more capacitors. As another example, if at least one of the two or more capacitors has negative capacitance, the total capacitance of the two or more capacitors may have a positive value and may be greater than the absolute value of the capacitance of each of the two or more capacitors.

If the ferroelectric material film having a negative capacitance and the paraelectric material film having a positive capacitance are connected in series, the total capacitance of the ferroelectric material film and the paraelectric material film may increase. Accordingly, a transistor having the ferroelectric material film may have a sub-threshold swing (SS) of less than 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. For example, the hafnium zirconium oxide may be a material obtained by doping hafnium oxide with zirconium (Zr). In another example, the hafnium zirconium oxide may be a compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), Si, calcium (Ca), cerium (Ce), dysprosium (Dy), erbium (Er), gadolinium (Gd), Ge, scandium (Sc), strontium (Sr), and Sn. The type of dopant may vary depending on the type of material of the ferroelectric material film.

If the ferroelectric material film includes hafnium oxide, the dopant of the ferroelectric material film may include, for example, at least one of Gd, Si, Zr, Al, and Y.

If the dopant of the ferroelectric material film is Al, the ferroelectric material film may include Al in a range of about 3 atomic % (at %) to about 8 at %. Here, the ratio of the dopant in the ferroelectric material film may refer to the ratio of the sum of the amounts of Hf and Al to the amount of Al in the ferroelectric material film.

If the dopant of the ferroelectric material film is Si, the ferroelectric material film may include Si in a range of about 2 at % to about 10 at %. If the dopant of the ferroelectric material film is Y, the ferroelectric material film may include Y in a range of about 2 at % to about 10 at %. If the dopant of the ferroelectric material film is Gd, the ferroelectric material film may include Gd in a range of about 1 at % to about 7 at % of Gd. If the dopant of the ferroelectric material film is Zr, the ferroelectric material film may include Zr in a range of about 50 at % to about 80 at %.

The paraelectric material film may include paraelectric properties. The paraelectric material film may include, for example, at least one of silicon oxide and a high-k metal oxide. The high-k metal oxide may include, for example, at least one of hafnium oxide, zirconium oxide, and aluminum oxide, but embodiments are not limited thereto.

The ferroelectric material film and the paraelectric material film may include the same material. The ferroelectric material film may have ferroelectric properties, but the paraelectric material film may not have ferroelectric properties. For example, if the ferroelectric material film and the paraelectric material film include hafnium oxide, the hafnium oxide included in the ferroelectric material film may have a different crystalline structure from the hafnium oxide included in the paraelectric material film.

The ferroelectric material film may be thick enough to exhibit ferroelectric properties. The ferroelectric material film may have a thickness of, for example, about 0.5 nanometers (nm) to about 10 nm, but embodiments are not limited thereto. A critical thickness that may exhibit ferroelectric properties may vary depending on the type of ferroelectric material, and thus, the thickness of the ferroelectric material film may vary depending on the type of ferroelectric material included in the ferroelectric material film.

For example, each of the first and second gate insulating layers 121 and 122 may include a ferroelectric material film. In another example, each of the first and second gate insulating layers 121 and 122 may include a plurality of ferroelectric material films that are spaced apart from each other. Each of the first and second gate insulating layers 121 and 122 may include a stack of a plurality of ferroelectric material films and a plurality of paraelectric material films that are alternately stacked with the ferroelectric material films.

The first etching stop layer 140 may be disposed on the sidewalls, in the first horizontal direction DR1, of each of the first gate spacer 111, the second gate spacer 112, and the third gate spacer 113. The first etching stop layer 140 may also be disposed on the upper surfaces of the first and second source/drain regions SD1 and SD2. In some embodiments, the first etching stop layer 140 may be disposed on the sidewalls, in the second horizontal direction DR2, of each of the first and second source/drain regions SD1 and SD2. For example, the first etching stop layer 140 may be conformally formed. The first etching stop layer 140 may include, for example, at least one of aluminum oxide, aluminum nitride, hafnium oxide, zirconium oxide, silicon oxide, silicon nitride, silicon oxynitride, and a low-k material.

The first capping pattern 131 may extend in the second horizontal direction DR2 over each of the first gate spacer 111, the first gate insulating layer 121, and the first gate electrode G1. The second capping pattern 132 may extend in the second horizontal direction DR2 over each of the second gate spacer 112, the second gate insulating layer 122, and the second gate electrode G2. The third capping pattern 133 may extend in the second horizontal direction DR2 over the third gate spacer 113 and the second portion 162 of the active cut 160. For example, the third capping pattern 133 may be in contact with the upper surface of the second portion 162 of the active cut 160. For example, the lowermost surface of the third capping pattern 133 may be formed lower than the uppermost surface of the second portion 162 of the active cut 160. For example, at least some of the second portion 162 of the active cut 160 may extend into the interior of the third capping pattern 133. For example, at least some of the second portion 162 of the active cut 160 may overlap with the third capping pattern 133 in the first horizontal direction DR1.

For example, the upper surfaces of the first, second, and third capping patterns 131, 132, and 133 may be formed on the same plane. For example, the upper surface of the second portion 162 of the active cut 160 may be formed lower than the upper surface of the third capping pattern 133. For example, the lower surface of the first capping pattern 131 may be in contact with the upper surfaces of the first gate spacer 111. The lower surface of the second capping pattern 132 may be in contact with the upper surfaces of the second gate spacer 112. The lower surface of the third capping pattern 133 may be in contact with the upper surfaces of the third gate spacer 113. For example, the lower surfaces of the first, second, and third capping patterns 131, 132, and 133 may be in contact with the first etch stop layer 140, but embodiments are not limited thereto. In some embodiments, the sidewalls of the first, second, and third capping patterns 131, 132, and 133 may be in contact with the first etch stop layer 140.

For example, the first, second, and third capping patterns 131, 132, and 133 may include an insulating material. The first, second, and third capping patterns 131, 132, and 133 may include, for example, at least one of SiN, SiON, SiO₂, SiCN, SiOCN, and a combination thereof, but embodiments are not limited thereto. For example, the first, second, and third capping patterns 131, 132, and 133 may include a different material from the active cut 160, but embodiments are not limited thereto. In some embodiments, the first, second, and third capping patterns 131, 132, and 133 may include the same material as the active cut 160.

The first upper interlayer insulating layer 150 may be disposed on the first etching stop layer 140. The first upper interlayer insulating layer 150 may be disposed on the sidewalls of each of the first, second, and third capping patterns 131, 132, and 133. The first upper interlayer insulating layer 150 may cover each of the first and second source/drain regions SD1 and SD2 on the field insulating layer 105. For example, the upper surface of the first upper interlayer insulating layer 150 may be formed on the same plane as the upper surfaces of the first, second, and third capping patterns 131, 132, and 133. However, embodiments are not limited thereto. In some embodiments, the first upper interlayer insulating layer 150 may cover the upper surfaces of the first, second, and third capping patterns 131, 132, and 133. The first upper interlayer insulating layer 150 may include, for example, at least one of silicon oxide, silicon nitride, silicon oxynitride, and a low-k material.

The upper source/drain contact UCA may be disposed between the first and second gate electrodes G1 and G2. The upper source/drain contact UCA may be disposed above the first source/drain region SD1. The upper source/drain contact UCA may extend into the first source/drain region SD1 by penetrating the first upper interlayer insulating layer 150 and the first etching stop layer 140 in the vertical direction DR3. The upper source/drain contact UCA may be electrically connected to the first source/drain region SD1. In FIG. 2, the upper source/drain contact UCA is illustrated as being formed as a single layer, but embodiments are not limited thereto. In some embodiments, the upper source/drain contact UCA may be formed as a multilayer.

For example, the upper surface of the upper source/drain contact UCA may be formed on the same plane as the upper surface of the first upper interlayer insulating layer 150, but embodiments are not limited thereto. In some embodiments, the upper surface of the upper source/drain contact UCA may be formed higher than the upper surface of the first upper interlayer insulating layer 150. For example, the upper surface of the upper source/drain contact UCA may be formed higher than the upper surface of the second portion 162 of the active cut 160. The upper source/drain contact UCA may include a conductive material. The upper silicide layer USL may be disposed between the upper source/drain contact UCA and the first source/drain region SD1. The upper silicide layer USL may be disposed along the boundary between the upper source/drain contact UCA and the first source/drain region SD1. For example, the upper silicide layer USL may include a metal silicide material.

The gate contact CB may be located above the first gate electrode G1. The gate contact CB may be connected to the first gate electrode G1 by penetrating the first capping pattern 131 in the vertical direction DR3. In FIG. 3, the gate contact CB is illustrated as being formed as a single layer, but embodiments are not limited thereto. In some embodiments, the gate contact CB may be formed as a multilayer. For example, the upper surface of the gate contact CB may be formed on the same plane as the upper surfaces of the upper source/drain contact UCA and the first upper interlayer insulating layer 150, but embodiments are not limited thereto. The gate contact CB may include a conductive material.

The bottom source/drain contact BCA may be disposed between the active cut 160 and the second gate electrode G2. The bottom source/drain contact BCA may be disposed below the second source/drain region SD2. The bottom source/drain contact BCA may be electrically connected to the second source/drain region SD2 by penetrating the lower interlayer insulating layer 100 and the insulating pattern 101 in the vertical direction DR3. For example, the bottom source/drain contact BCA may overlap with the first portion 161 of the active cut 160 in the first horizontal direction DR1. For example, the bottom source/drain contact BCA may be spaced apart from the first portion 161 of the active cut 160 in the first horizontal direction DR1. However, embodiments are not limited thereto. In some embodiments, the bottom source/drain contact BCA may be in contact with the first portion 161 of the active cut 160.

For example, the bottom source/drain contact BCA may be formed as a single layer, but embodiments are not limited thereto. In some embodiments, the bottom source/drain contact BCA may be formed as a multilayer. For example, both sidewalls, in the first horizontal direction DR1, of the bottom source/drain contact BCA may contact the insulating pattern 101 and the lower interlayer insulating layer 100. For example, the lower surface of the bottom source/drain contact BCA may be formed on the same plane as the lower surface of the lower interlayer insulating layer 100. The bottom source/drain contact BCA may include a conductive material. The lower silicide layer BSL may be disposed between the bottom source/drain contact BCA and the second source/drain region SD2. The lower silicide layer BSL may be disposed along the boundary between the bottom source/drain contact BCA and the second source/drain region SD2. The lower silicide layer BSL may include, for example, a metal silicide material.

The second etching stop layer 180 may be disposed on the upper surfaces of the upper source/drain contact UCA, the first, second, and third capping patterns 131, 132, and 133, and the first upper interlayer insulating layer 150. For example, the second etching stop layer 180 may be spaced apart from the upper surface of the second portion 162 of the active cut 160 in the vertical direction DR3. In FIGS. 2 and 4, the second etching stop layer 180 is illustrated as being formed as a single layer, but embodiments are not limited thereto. In some embodiments, the second etching stop layer 180 may be formed as a multilayer. The second etching stop layer 180 may include, for example, at least one of aluminum oxide, aluminum nitride, hafnium oxide, zirconium oxide, silicon oxide, silicon nitride, silicon oxynitride, and a low-k material. The second upper interlayer insulating layer 185 may be disposed on the second etching stop layer 180. The second upper interlayer insulating layer 185 may include at least one of silicon oxide, silicon nitride, silicon oxynitride, and a low-k material.

The first via V1 may be connected to the upper source/drain contact UCA by penetrating the second upper interlayer insulating layer 185 and the second etching stop layer 180 in the vertical direction DR3. Similarly, the second via V2 may be connected to the gate contact CB by penetrating the second upper interlayer insulating layer 185 and the second etching stop layer 180 in the vertical direction DR3. In FIGS. 2 and 3, the first and second vias V1 and V2 are illustrated as being formed as single layers, but embodiments are not limited thereto. In some embodiments, the first and second vias V1 and V2 may be formed as multilayers. The first and second vias V1 and V2 may include a conductive material.

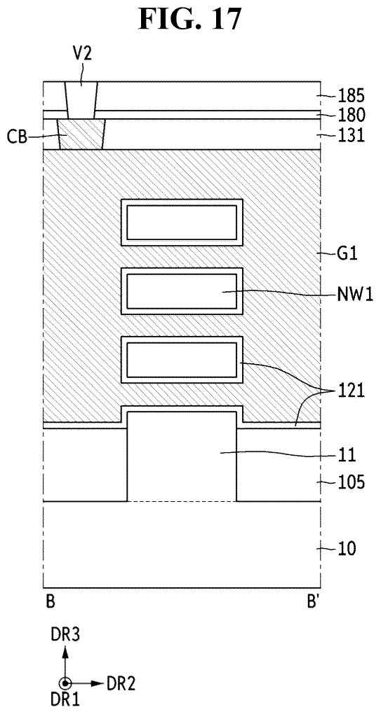

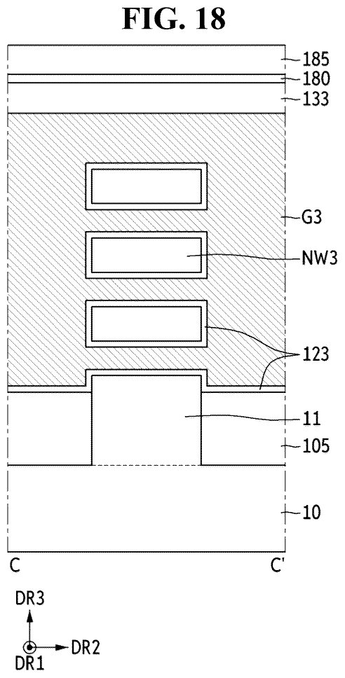

An example of a method of fabricating a semiconductor device according to some embodiments of the present disclosure is described below with reference to FIGS. 2 and 5 through 36.

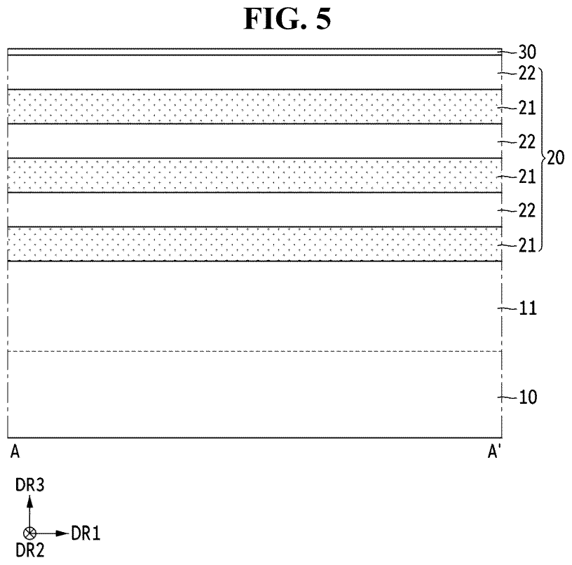

FIGS. 5 through 36 are cross-sectional views for explaining intermediate steps of a method of fabricating a semiconductor device according to some embodiments of the present disclosure.

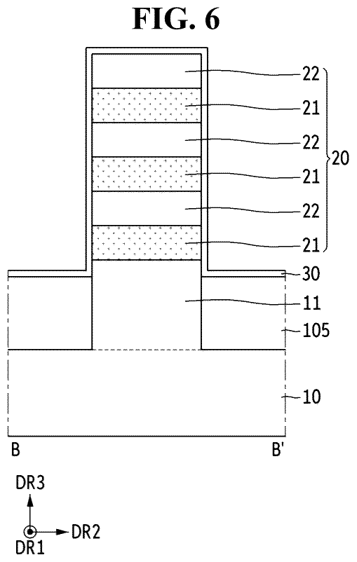

Referring to FIGS. 5 and 6, a substrate 10 may be provided. The substrate 10 may be a Si substrate or a silicon-on-insulator (SOI) substrate. In some embodiments, the substrate 10 may include SiGe, SiGe-on-insulator (SGOI), indium antimonide, lead telluride compounds, indium arsenide, indium phosphide, gallium arsenide, or gallium antimonide, but embodiments are not limited thereto.

Thereafter, a stacked structure 20 may be formed on the upper surface of the substrate 10. The stacked structure 20 may include first semiconductor layers 21 and second semiconductor layers 22, which are stacked on the upper surface of the substrate 10, alternating with the first semiconductor layers 21. For example, the first semiconductor layers 21 may be formed at the top of the stacked structure 20, and the second semiconductor layers 22 may be formed at the bottom of the second semiconductor layer 22. However, embodiments are not limited thereto. In some embodiments, the first semiconductor layers 21 may also be formed at the top of the stacked structure 20. The first semiconductor layers 21 may include, for example, SiGe. The second semiconductor layers 22 may include, for example, Si.

Thereafter, part of the stacked structure 20 may be etched. During the etching of the stacked structure 20, part of the substrate 10 may also be etched. Through this etching process, an active pattern 11 may be defined on the upper surface of the substrate 10, below the stacked structure 20. The active pattern 11 may protrude from the upper surface of the substrate 10 in the vertical direction DR3. The active pattern 11 may extend in the first horizontal direction DR1.

Thereafter, a field insulating layer 105 may be formed on the upper surface of the substrate 10. The field insulating layer 105 may surround the sidewalls of the active pattern 11. For example, the upper surface of the active pattern 11 may be formed higher than the upper surface of the field insulating layer 105. Thereafter, a pad oxide layer 30 may be formed to cover the upper surface of the field insulating layer 105, the exposed sidewalls of the active pattern 11, and the sidewalls and upper surface of the stacked structure 20. For example, the pad oxide layer 30 may be conformally formed. The pad oxide layer 30 may include, for example, SiO₂.

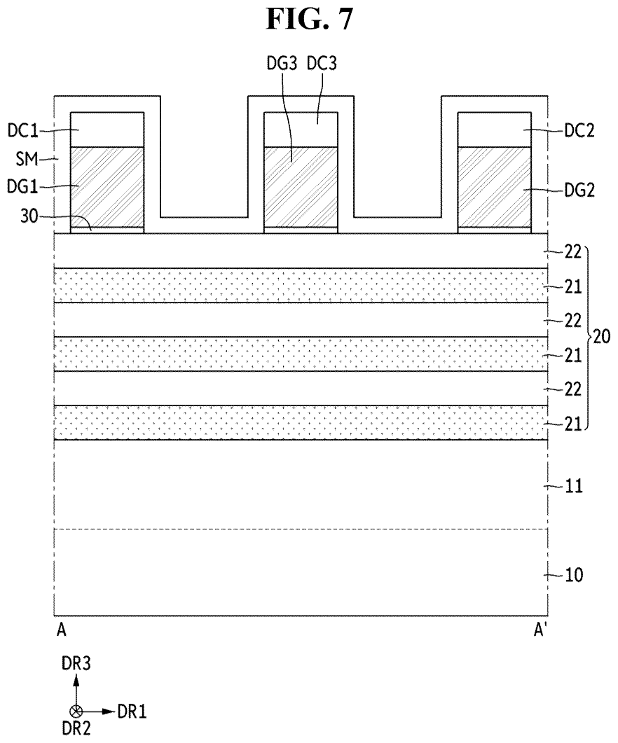

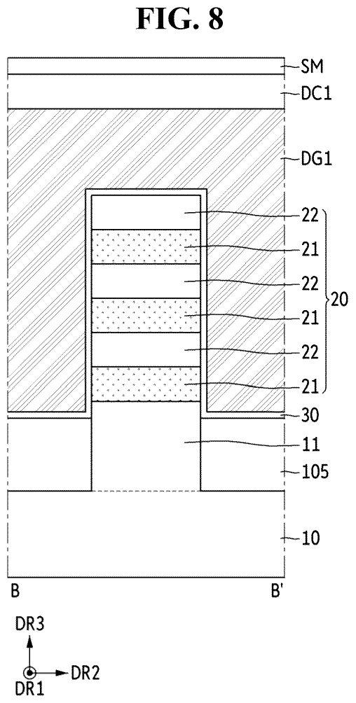

Referring to FIGS. 7 and 8, a first dummy gate DG1, a second dummy gate DG2, and a third dummy gate DG3, which may extend in the second horizontal direction DR2, and a first dummy capping pattern DC1, a second dummy capping pattern DC2, and a third dummy capping pattern DC3, which may also extend in the second horizontal direction DR2, may be formed on the pad oxide layer 30, on the stacked structure 20 and the field insulating layer 105. For example, the third dummy gate DG3 may be spaced apart from the first dummy gate DG1 in the first horizontal direction DR1, and the second dummy gate DG2 may be spaced from the third dummy gate DG3 in the first horizontal direction DR1. The first dummy capping pattern DC1 may be disposed on the first dummy gate DG1. The second dummy capping pattern DC2 may be disposed on the third dummy gate DG3. The third dummy capping pattern DC3 may be disposed on the third dummy gate DG3.

During the formation of the first, second, and third dummy gates DG1, DG2, and DG3, and the first, second, and third dummy capping patterns DC1, DC2, and DC3, the entire pad oxide layer 30, except for portions that overlap with the first, second, and third dummy gates DG1, DG2, and DG3 in the vertical direction DR3, may be removed.

Thereafter, a spacer material layer SM may be formed to cover the sidewalls and upper surfaces of the first, second, and third dummy gates DG1, DG2, and DG3, the first, second, and third dummy capping patterns DC1, DC2, and DC3, the exposed sidewalls and upper surfaces of the stacked structure 20, and the upper surface of the field insulating layer 105. For example, the spacer material layer SM may be conformally formed. The spacer material layer SM may include, for example, SiN, SiON, SiO₂, SiOCN, SiBN, SiOBN, SiOC, and a combination thereof.

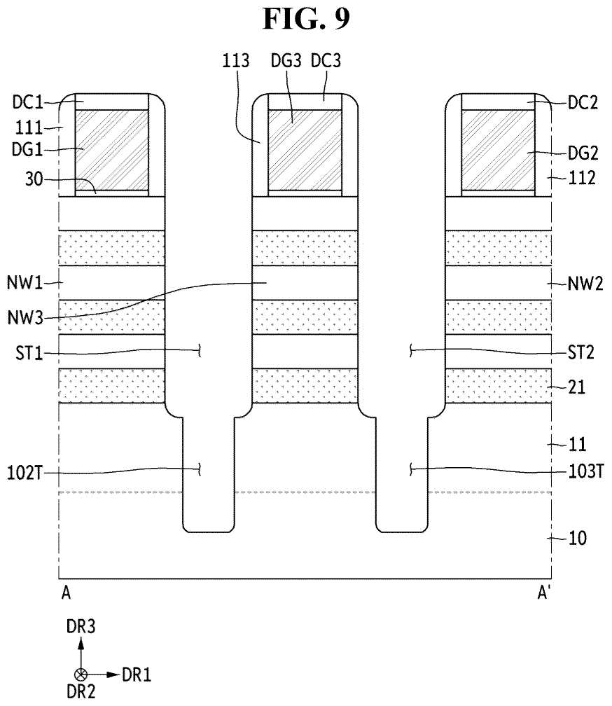

Referring to FIG. 9, a first source/drain trench ST1 and a second source/drain trench ST2 may be formed by etching the stacked structure 20 and the active pattern 11 using the first, second, and third dummy gates DG1, DG2, and DG3 and the first, second, and third dummy capping patterns DC1, DC2, and DC3 as a mask. The first source/drain trench ST1 may be formed between the first and third dummy gates DG1 and DG3. The second source/drain trench ST2 may be formed between the second and third dummy gates DG2 and DG3.

Additionally, a first sacrificial pattern trench 102T may be formed below the first source/drain trench ST1, and a second sacrificial pattern trench 103T may be formed below the second source/drain trench ST2. For example, the first and second sacrificial pattern trenches 102T and 103T may penetrate the active pattern 11 in the vertical direction DR3 and extend into the interior of the substrate 10. For example, the lower surfaces of the first and second sacrificial pattern trenches 102T and 103T may be defined by the substrate 10. For example, the widths, in the first horizontal direction DR1, of the first and second sacrificial pattern trenches 102T and 103T may be smaller than the width, in the first horizontal direction DR1, of each of the first and second source/drain trenches ST1 and ST2, but embodiments are not limited thereto.

For example, during the formation of the first and second source/drain trenches ST1 and ST2 and the first and second sacrificial pattern trenches 102T and 103T, parts of the first, second, and third dummy capping patterns DC1, DC2, and DC3 and parts of the spacer material layer SM on the upper surfaces of the first, second, and third dummy capping patterns DC1, DC2, and DC3 may be etched. Parts of the spacer material layer SM that remain on the sidewalls of each of the first, second, and third dummy capping patterns DC1, DC2, and DC3 and on the sidewalls of each of the first, second, and third dummy gates DG1, DG2, and DG3 may be defined as a first gate spacer 111, a second gate spacer 112, and a third gate spacer 113.

After the formation of the first and second source/drain trenches ST1 and ST2 and the first and second sacrificial pattern trenches 102T and 103T, the second semiconductor layers 22 that remain below the first dummy gate DG1 on the active pattern 11 may be defined as first plurality of nanosheets NW1. After the formation of the first and second source/drain trenches ST1 and ST2 and the first and second sacrificial pattern trenches 102T and 103T, the second semiconductor layers 22 that remain below the second dummy gate DG2 on the active pattern 11 may be defined as second plurality of nanosheets NW1. After the formation of the first and second source/drain trenches ST1 and ST2 and the first and second sacrificial pattern trenches 102T and 103T, the second semiconductor layers 22 that remain below the third dummy gate DG3 on the active pattern 11 may be defined as third plurality of nanosheets NW3.

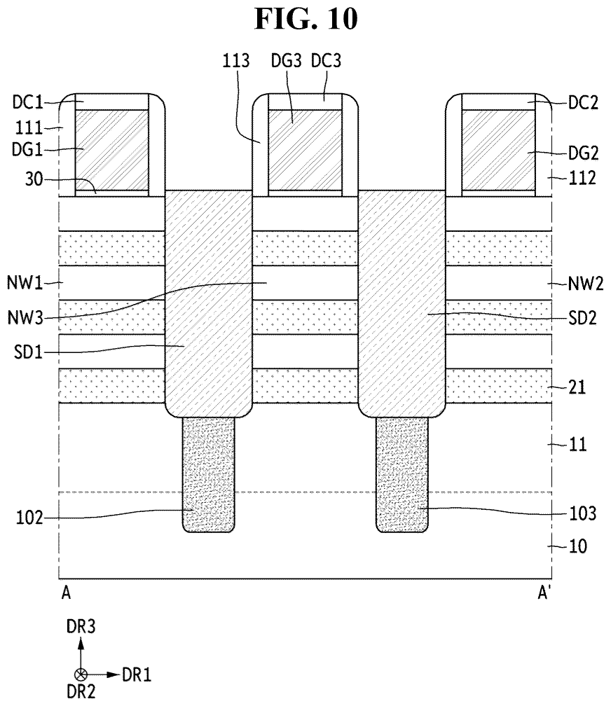

Referring to FIG. 10, a first sacrificial pattern 102 may be formed within the first sacrificial pattern trench 102T. Additionally, a second sacrificial pattern 103 may be formed within the second sacrificial pattern trench 103T. For example, the upper surfaces of the first and second sacrificial patterns 102 and 103 may be formed lower than the uppermost surface of the active pattern 11. For example, the sidewalls, in the first horizontal direction DR1, of each of the first and second sacrificial patterns 102 and 103 may be respectively in contact with the active pattern 11 and the substrate 10. The lower surfaces of the first and second sacrificial patterns 102 and 103 may be in contact with the substrate 10. For example, the first and second sacrificial patterns 102 and 103 may include SiGe.

Thereafter, a first source/drain region SD1 may be formed within the first source/drain trench ST1. For example, the lower surface of the first source/drain region SD1 may be in contact with the first sacrificial pattern 102. For example, the first source/drain region SD1 may be in contact with the sidewalls, in the first horizontal direction DR1, of both the first plurality of nanosheets NW1 and third plurality of nanosheets NW3. Additionally, a second source/drain region SD2 may be formed within the second source/drain trench ST2. For example, the lower surface of the second source/drain region SD2 may be in contact with the second sacrificial pattern 103. The second source/drain region SD2 may be in contact with the sidewalls, in the first horizontal direction DR1, of both the second plurality of nanosheets NW2 and third plurality of nanosheets NW3.

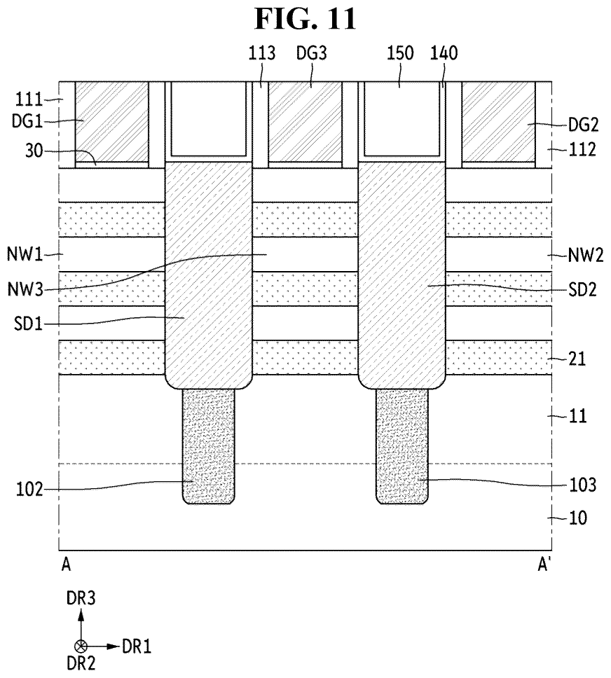

Referring to FIG. 11, a first etching stop layer 140 may be formed on the exposed sidewalls of each of the first, second, and third gate spacers 111, 112, and 113, the exposed upper surfaces of the first, second, and third dummy capping patterns DC1, DC2, and DC3, and the exposed surfaces of the first and second source/drain regions SD1 and SD2. Thereafter, a first upper interlayer insulating layer 150 may be formed on the first etching stop layer 140. Thereafter, the upper surfaces of the first, second, and third dummy gates DG1, DG2, and DG3 may be exposed through a planarization process.

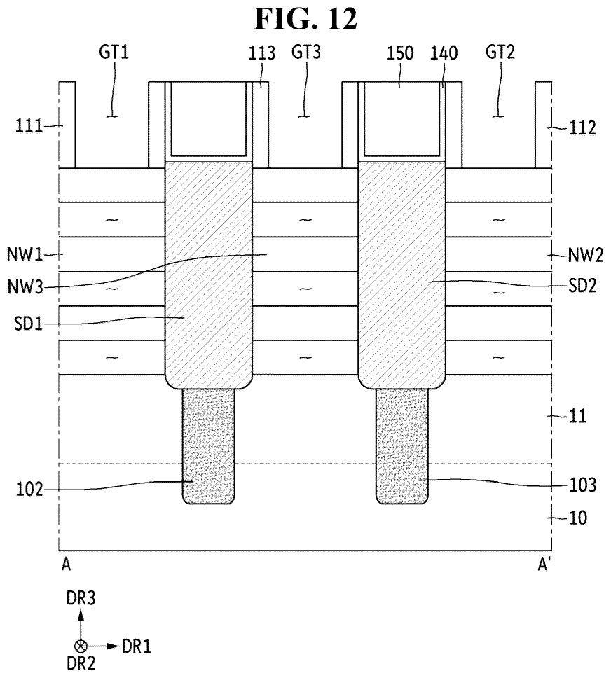

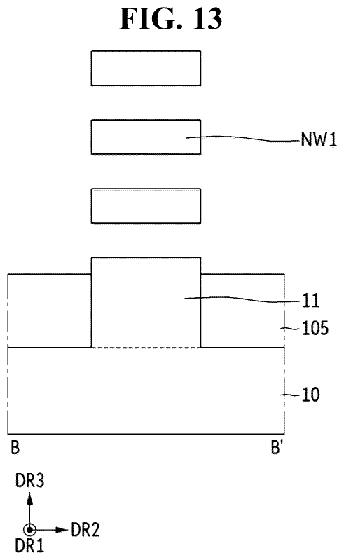

Referring to FIGS. 12 and 13, the first, second, and third dummy gates DG1, DG2, and DG3, the pad oxide layer 30, and the first semiconductor layers 21 may each be etched. For example, the place from which the first dummy gate DG1, the pad oxide layer 30, and the first semiconductor layers 21 have been removed may be defined as a first gate trench GT1. Similarly, the place from which the second dummy gate DG2, the pad oxide layer 30, and the first semiconductor layers 21 have been removed may be defined as a second gate trench GT2. The place from which the third dummy gate DG3, the pad oxide layer 30, and the first semiconductor layers 21 have been removed may be defined as a third gate trench GT3.

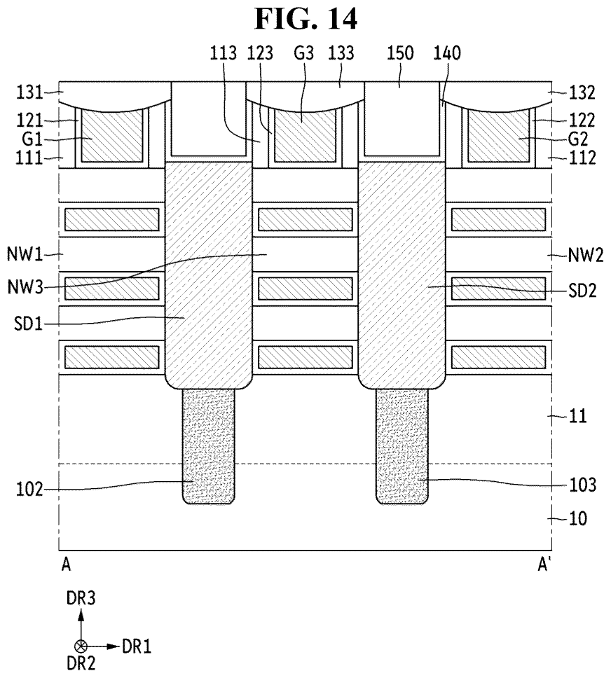

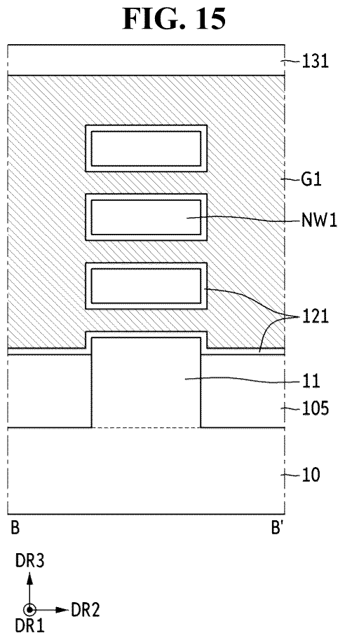

Referring to FIGS. 14 and 15, a first gate insulating layer 121, a first gate electrode G1, and a first capping pattern 131 may be sequentially formed in the first gate trench GT1. Additionally, a second gate insulating layer 122, a second gate electrode G2, and a second capping pattern 132 may be sequentially formed in the second gate trench GT2, and a third gate insulating layer 123, a third gate electrode G3, and a third capping pattern 133 may be sequentially formed in the third gate trench GT3. For example, the first gate electrode G1 may surround the first plurality of nanosheets NW1, the second gate electrode G2 may surround the second plurality of nanosheets NW2, and the third gate electrode G3 may surround the third plurality of nanosheets NW2.

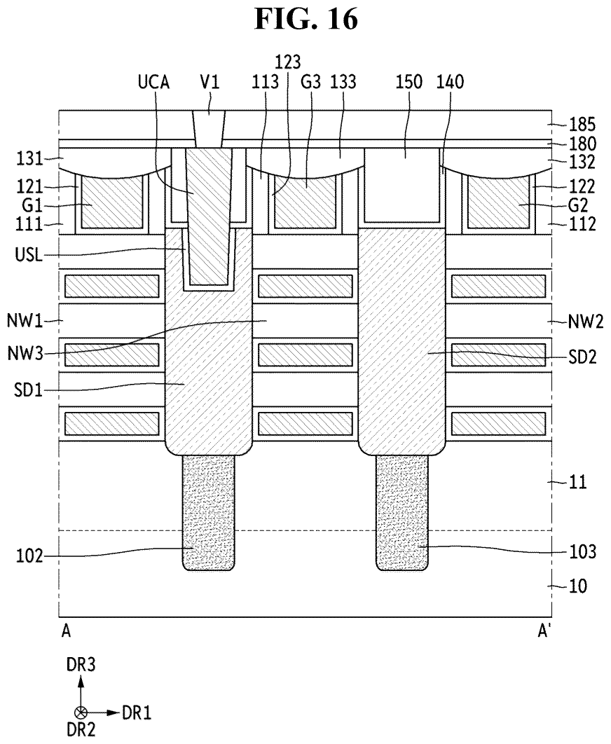

Referring to FIGS. 16 through 18, an upper source/drain contact UCA may be formed on the first source/drain region SD1. The upper source/drain contact UCA may extend into the first source/drain region SD1 by penetrating the first upper interlayer insulating layer 150 and the first etching stop layer 140 in the vertical direction DR3. Additionally, an upper silicide layer USL may be formed between the first source/drain region SD1 and the upper source/drain contact UCA. Furthermore, a gate contact CB, which is connected to the first gate electrode G1 by penetrating the first capping pattern 131 in the vertical direction DR3, may be formed.

Thereafter, a second etching stop layer 180 and a second upper interlayer insulating layer 185 may be sequentially formed on the upper surfaces of the first upper interlayer insulating layer 150, the first, second, and third capping patterns 131, 132, and 133, and the upper source/drain contact UCA. Thereafter, a first via V1, which may be connected to the upper source/drain contact UCA by penetrating the second etching stop layer 180 and the second upper interlayer insulating layer 185 in the vertical direction DR3, may be formed. Also, a second via V2, which may be connected to the gate contact CB by penetrating the second etching stop layer 180 and the second upper interlayer insulating layer 185 in the vertical direction DR3, may be formed.

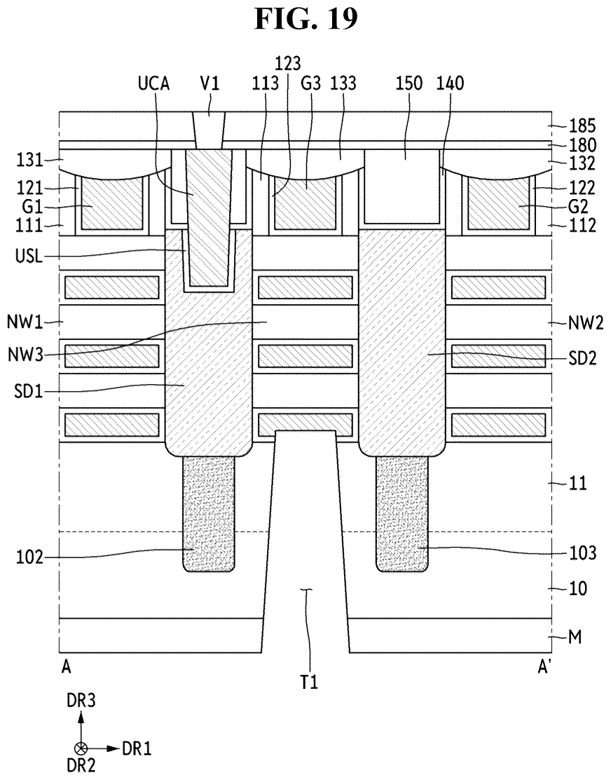

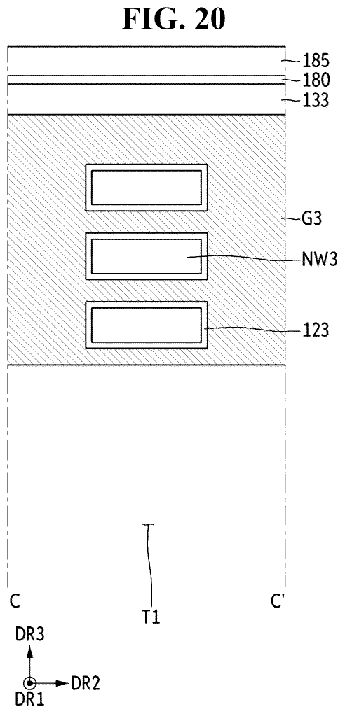

Referring to FIGS. 19 and 20, a mask pattern M may be formed on the lower surface of the substrate 10. For example, the mask pattern M may expose the substrate 10 formed below the third gate electrode G3. Thereafter, using the mask pattern M as a mask, the substrate 10 and the active pattern 11 may be etched, thereby forming a first trench T1. For example, the first trench T1 may be formed between the first and second sacrificial patterns 102 and 103. The first trench T1 may extend in the second horizontal direction DR2.

For example, the first trench T1 may etch through the third gate insulating layer 123 to extend into the interior of the third gate electrode G3. Thus, the third gate electrode G3 may be exposed through the upper surface of the first trench T1. For example, the upper surface of the first trench T1 may be formed higher than the uppermost surface of the active pattern 11. For example, the upper surface of the first trench T1 may be formed lower than the lower surface of the lowermost nanosheet of the third plurality of nanosheets NW3. For example, the width, in the first horizontal direction DR1, of the first trench T1 may continuously decrease in a direction toward the upper surface of the first trench T1.

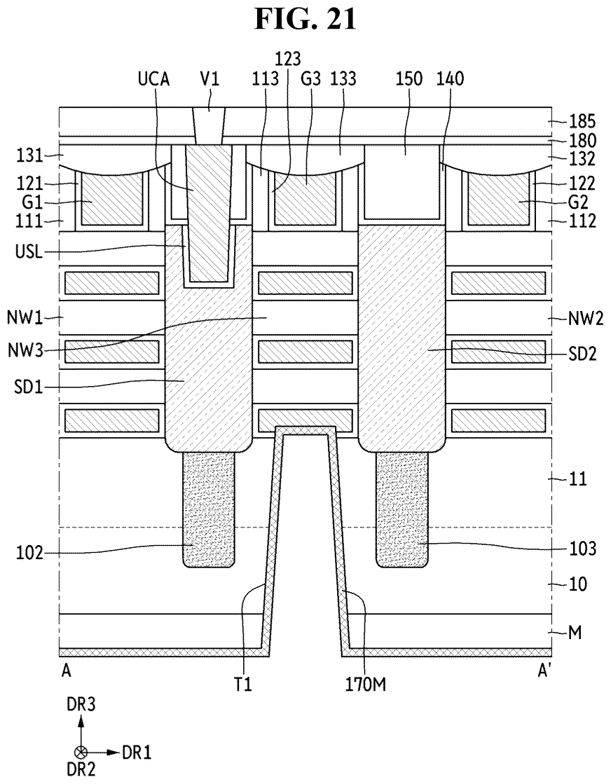

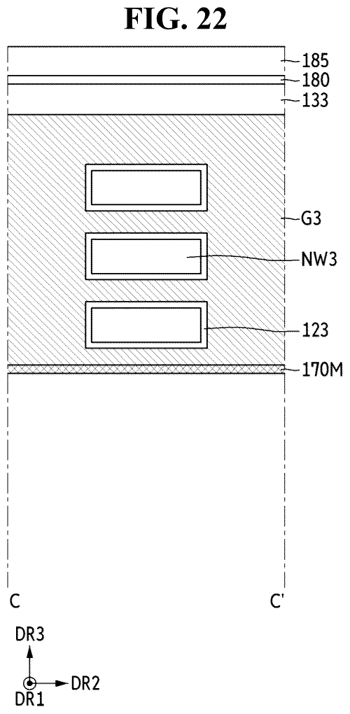

Referring to FIGS. 21 and 22, a liner material layer 170M may be formed along the upper surface and sidewalls of the first trench T1. For example, the liner material layer 170M may be formed even on the lower surface of the mask pattern M. For example, the liner material layer 170M may be conformally formed. For example, the liner material layer 170M may include an insulating material. For example, the liner material layer 170M may include at least one of SiN, SiON, SiCN, SiOCN, SiOC, and a combination thereof.

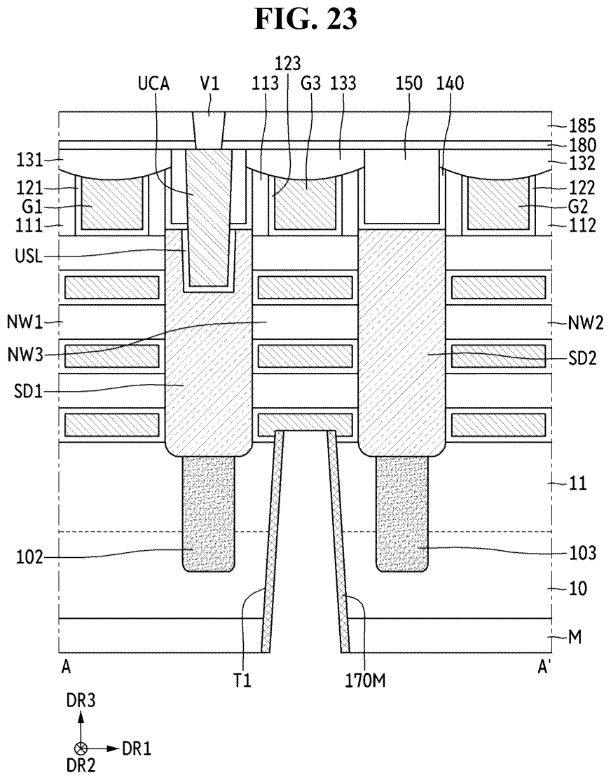

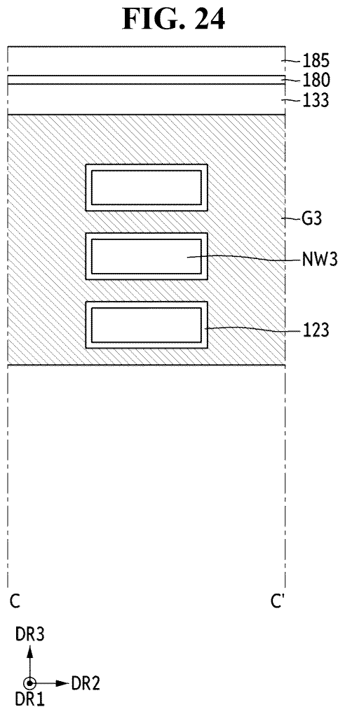

Referring to FIGS. 23 and 24, part of the liner material layer 170M may be etched by performing an etch-back process. For example, part of the liner material layer 170M formed on the upper surface of the first trench T1 may be etched away. As a result, the third gate electrode G3 may be exposed on the upper surface of the first trench T1. Additionally, part of the liner material layer 170M formed on the lower surface of the mask pattern M may be etched away. As a result, the lower surface of the mask pattern M may be exposed.

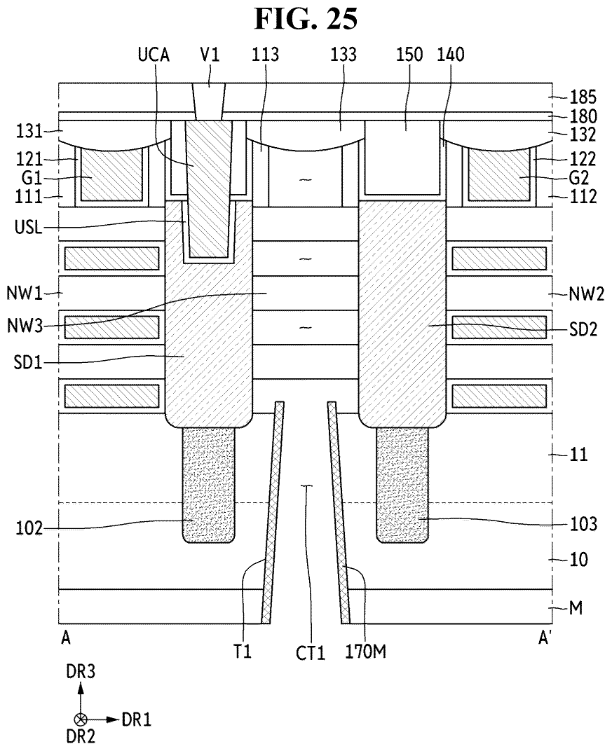

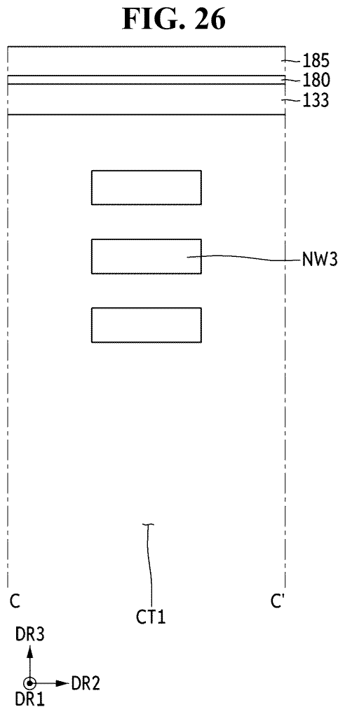

Referring to FIGS. 25 and 26, the third gate electrode G3 and the third gate insulating layer 123, which may be exposed through the first trench T1, may both be etched. For example, the third gate electrode G3 and the third gate insulating layer 123 may be etched through a wet etching process. The space formed between the region from which the third gate electrode G3 and the third gate insulating layer 123 have been etched and the liner material layer 170M may be defined as a first active cut trench CT1.

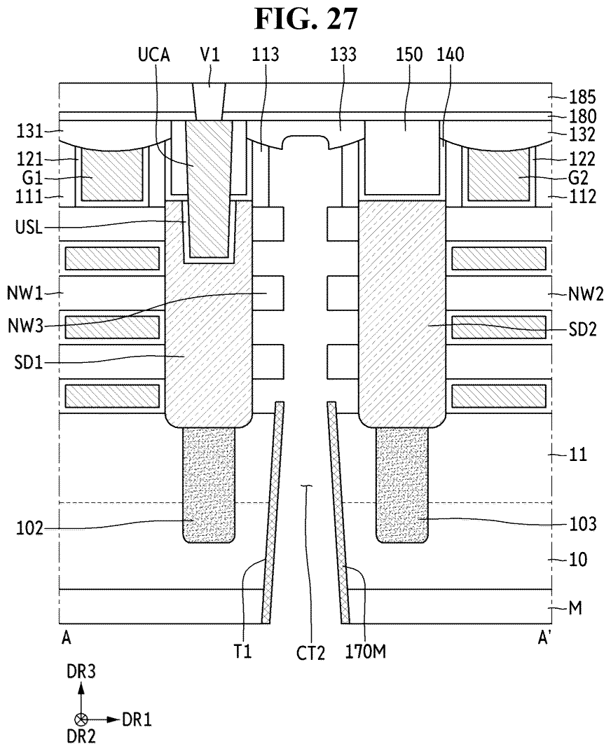

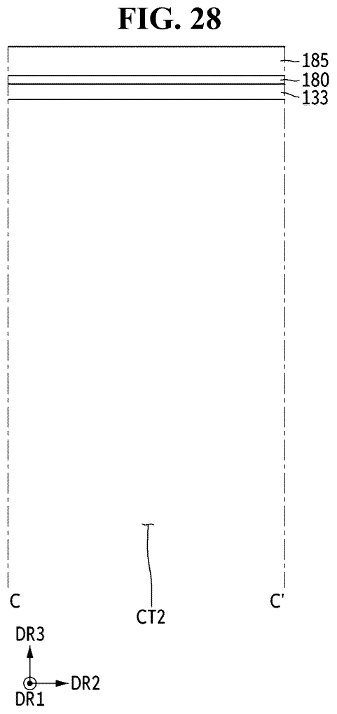

Referring to FIGS. 27 and 28, parts of the third plurality of nanosheets NW3 exposed through the first active cut trench CT1 may be etched. For example, while parts of the third plurality of nanosheets NW3 are being etched, part of the third capping pattern 133 may also be etched. For example, parts of the third plurality of nanosheets NW3 may be etched using a dry etching process. For example, the first active cut trench CT1 and the region from which parts of the third plurality of nanosheets NW3 have been etched may be defined as a second active cut trench CT2. For example, the third plurality of nanosheets NW3 may be separated by the second active cut trench CT2 into first portions contacting the first source/drain region SD1 and second portions contacting the second source/drain region SD2.

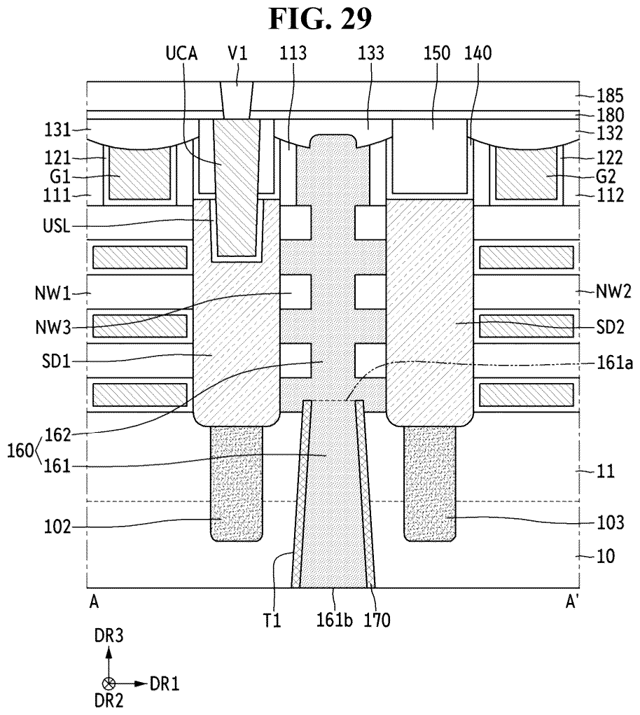

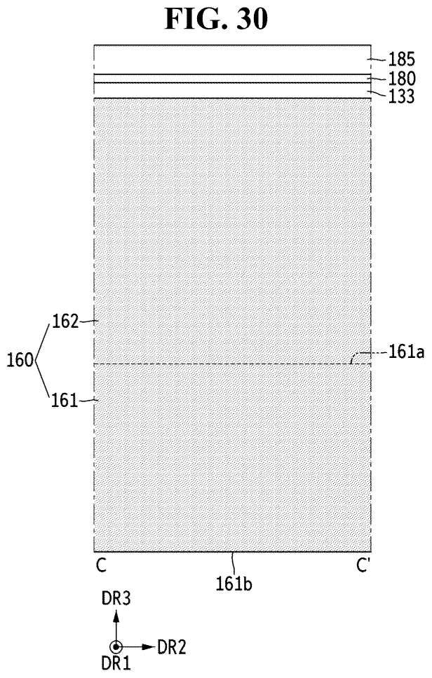

Referring to FIGS. 29 and 30, an active cut 160 may be formed within the second active cut trench CT2. Thereafter, the lower surface of the substrate 10 may be exposed by performing a planarization process. The liner material layer 170M that remains after the planarization process may be defined as a liner layer 170. For example, the liner layer 170 may be formed along the sidewalls of the first trench T1. For example, the active cut 160 may include a first portion 161 and a second portion 162. For example, the first portion 161 of the active cut 160 may be defined as a portion filling between parts of the liner layer 170 within part of the first trench T1. The second portion 162 of the active cut 160 may be defined as a portion filling the unfilled part of the second active cut trench CT2 on an upper surface 161a of the first portion 161 of the active cut 160.

For example, the upper surface of the first portion 161 of the active cut 160 may be formed higher than the uppermost surface of the active pattern 11. For example, the lower surface of the first portion 161 of the active cut 160 may be formed on the same plane as the lower surface of the substrate 10. For example, the second portion 162 of the active cut 160 may be in contact with the upper and lower surfaces of each of the third plurality of nanosheets NW3. For example, the second portion 162 of the active cut 160 may be in contact with the inner sidewalls of each of the third plurality of nanosheets NW3, separated in the first horizontal direction DR1. For example, the second portion 162 of the active cut 160 may be in contact with the third gate spacer 113. For example, the second portion 162 of the active cut 160 may be in contact with the lower surface of the third capping pattern 133. For example, at least some of the second portion 162 of the active cut 160 may extend into the interior of the third capping pattern 133.

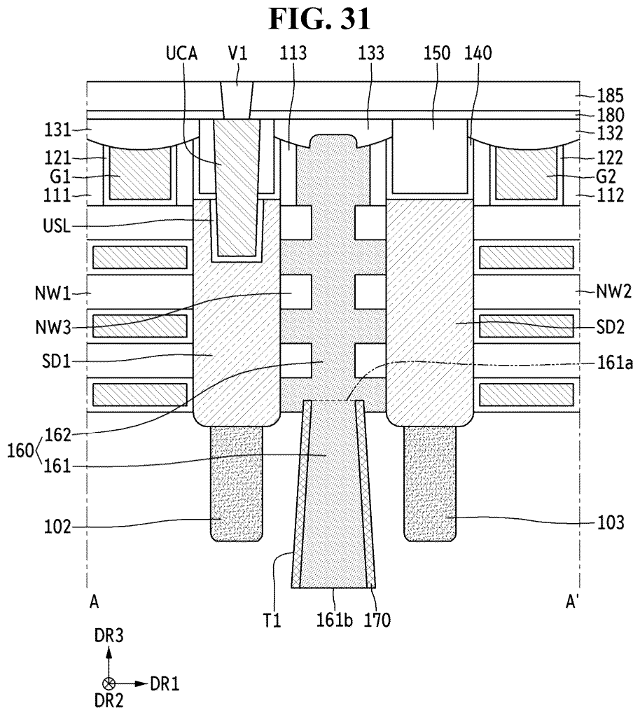

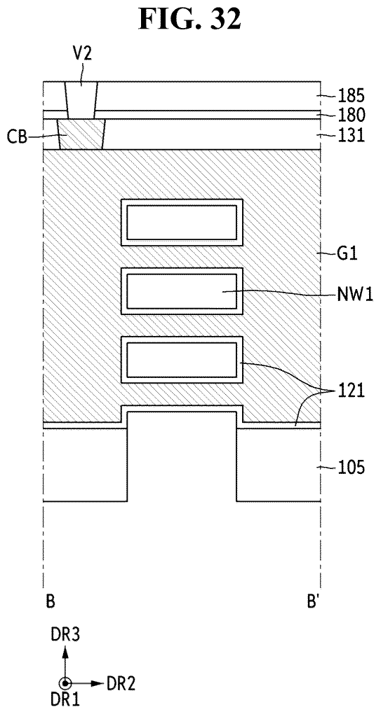

Referring to FIGS. 31 and 32, the substrate 10 and the active pattern 11 may be etched. As a result, the first and second sacrificial patterns 102 and 103 may be exposed.

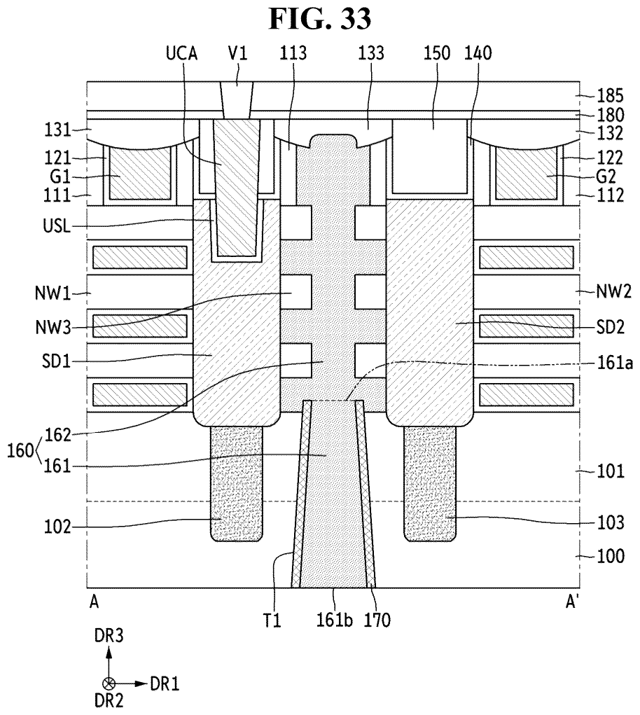

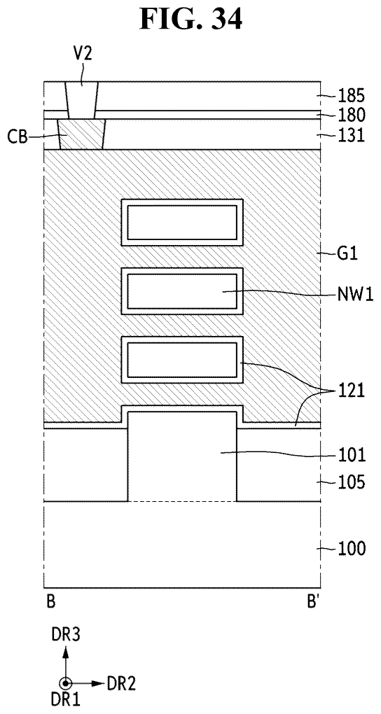

Referring to FIGS. 33 and 34, a lower interlayer insulating layer 100 and an insulating pattern 101 may be formed on the etched portions of the substrate 10 and the active pattern 11. For example, the insulating pattern 101 may be formed on the etched part of the active pattern 11. The insulating pattern 101 may be in contact with the first and second gate insulating layers 121 and 122, the first and second source/drain regions SD1 and SD2, the field insulating layer 105, and the first and second sacrificial patterns 102 and 103. The insulating pattern 101 may surround parts of the sidewalls of each of the first and second sacrificial patterns 102 and 103.

Additionally, the lower interlayer insulating layer 100 may be formed on the etched part of the substrate 10. The lower interlayer insulating layer 100 may be in contact with the field insulating layer 105 and the first and second sacrificial patterns 102 and 103. The lower interlayer insulating layer 100 may surround the remaining parts of the sidewalls of each of the first and second sacrificial patterns 102 and 103. Furthermore, the lower interlayer insulating layer 100 may cover the lower surfaces of the first and second sacrificial patterns 102 and 103. Thereafter, the lower surface 161b of the first portion 161 of the active cut 160 may be exposed by performing a planarization process.

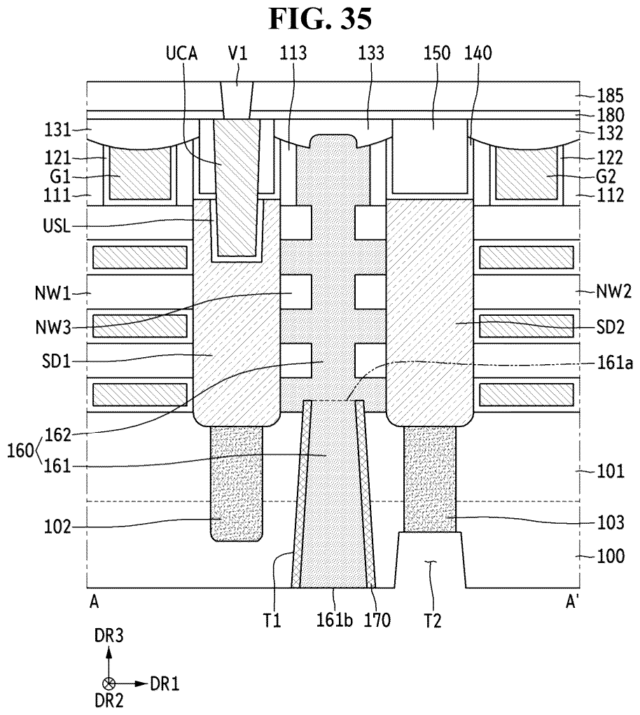

Referring to FIG. 35, a second trench T2, which may expose the lower surface of the second sacrificial pattern 103, may be formed within the lower interlayer insulating layer 100. For example, the second trench T2 may extend in the vertical direction DR3 from the lower surface of the lower interlayer insulating layer 100.

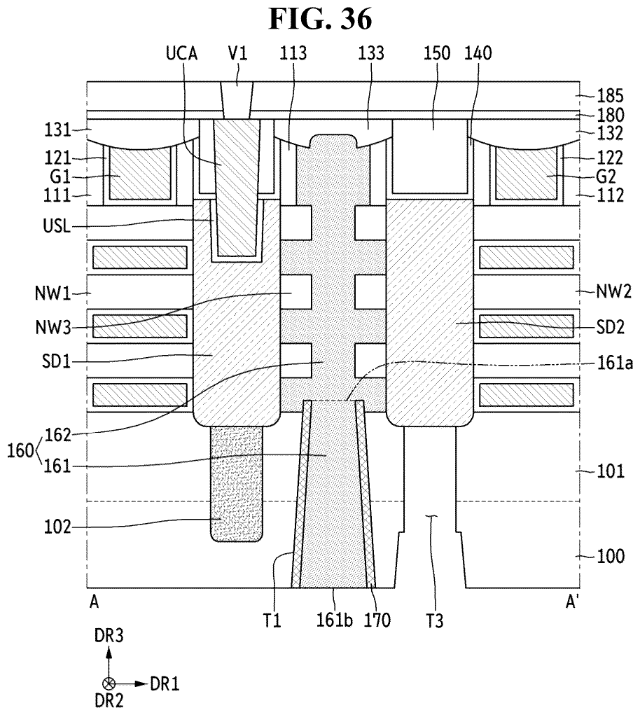

Referring to FIG. 36, the second sacrificial pattern 103, which may be exposed through the second trench T2, may be etched. As a result, a third trench T3 may be defined. For example, the second source/drain region SD2 may be exposed through the third trench T3.

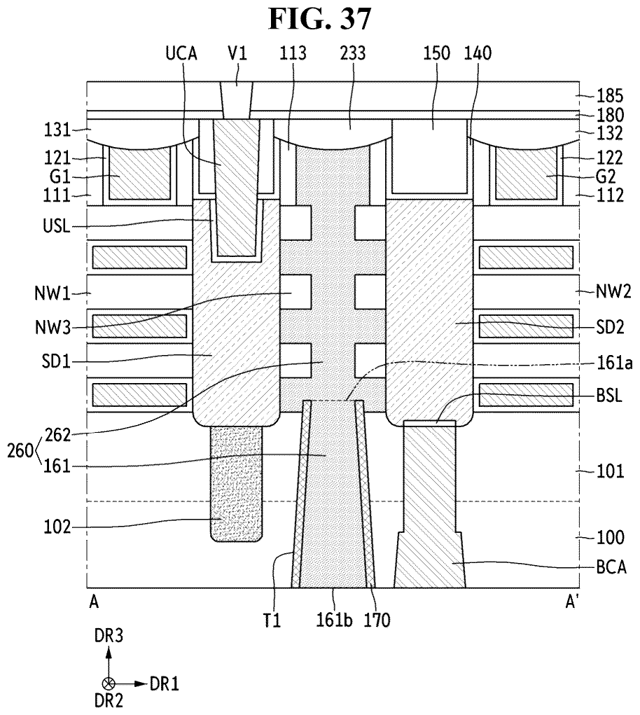

Referring to FIG. 37, a bottom source/drain contact BCA may be formed within the third trench T3. For example, the lower surface of the bottom source/drain contact BCA may be formed on the same plane as the lower surface of the lower interlayer insulating layer 100. For example, the bottom source/drain contact BCA may be spaced apart in the first horizontal direction DR1 from the first portion 161 of the active cut 160. The bottom source/drain contact BCA may also be spaced apart from the liner layer 170 in the first horizontal direction DR1. Additionally, a bottom silicide layer BSL may be formed between the bottom source/drain contact BCA and the second source/drain region SD2. Accordingly, the semiconductor device of FIG. 2 may be obtained.

In the example method of fabricating a semiconductor device discussed above according to some embodiments of the present disclosure, the active cut 160 may be formed from below the third gate electrode G3. For example, the active cut 160 may be formed through the first trench T1, which penetrates the substrate 10 and the active pattern 11 in the vertical direction DR3. As a result, the amount of etching required may be reduced compared to a case where the capping pattern 133 is formed to penetrate from above the third gate electrode G3 in the vertical direction DR3, and the difficulty of fabrication may be lowered. Additionally, by forming the active cut 160 from below the third gate electrode G3, process margins may be increased. Therefore, the first and second source/drain regions SD1 and SD2 may be prevented from being etched during the formation of the active cut 160.

In a semiconductor device manufactured by the example method according to some embodiments of the present disclosure, the active cut 160 may be in contact with the lower surface of the third capping pattern 133. Furthermore, in a semiconductor device manufactured by the example method according to some embodiments of the present disclosure, the width, in the first horizontal direction DR1, of the first portion 161 of the active cut 160, which penetrates the lower interlayer insulating layer 100 in the vertical direction DR3, may continuously decrease in a direction toward to the upper surface 161a of the active cut 160. Additionally, in a semiconductor device manufactured by the example method according to some embodiments of the present disclosure, the bottom source/drain contact BCA may be spaced apart in the first horizontal direction DR1 from the first portion 161 of the active cut 160.

An example of a semiconductor device according to some embodiments of the present disclosure is described below with reference to FIG. 37, focusing mainly on the differences from the examples described above with reference to FIGS. 1 through 4.

FIG. 37 is a cross-sectional view illustrating a semiconductor device according to some embodiments of the present disclosure.

Referring to FIG. 37, in the semiconductor device according to some embodiments of the present disclosure, a second portion 262 of an active cut 260 may not extend into the interior of a third capping pattern 233. For example, during the formation of a trench for forming the active cut 260, the lower surface of the third capping pattern 233 may be not etched. As a result, the upper surface of the second portion 262 of the active cut 260 may be in contact with the lower surface of the third capping pattern 233. For example, the lowermost surface of the third capping pattern 233 may be formed at the same height as the lowermost surface of the first capping pattern 131 and the lowermost surface of a second capping pattern 132.

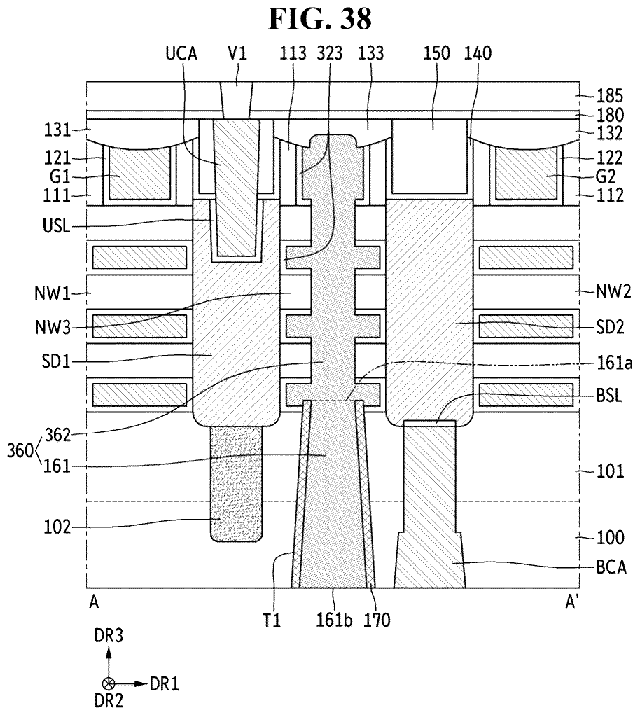

An example of a semiconductor device according to some embodiments of the present disclosure is described below with reference to FIG. 38, focusing mainly on the differences from the examples described above with reference to FIGS. 1 through 4.

FIG. 38 is a cross-sectional view illustrating a semiconductor device according to some embodiments of the present disclosure.

Referring to FIG. 38, in the semiconductor device according to some embodiments of the present disclosure, a third gate insulating layer 323 may be disposed between an active cut 360 and third gate spacer 113.

For example, the third gate insulating layer 323 may be disposed between a second portion 362 of the active cut 360 and the third gate spacer 113. The third gate insulating layer 323 may be disposed between the second portion 362 of the active cut 360 and a first source/drain region SD1. The third gate insulating layer 323 may be disposed between the second portion 362 of the active cut 360 and a second source/drain region SD2. The third gate insulating layer 323 may be disposed between the upper surface of an insulating pattern 101 and the second portion 362 of the active cut 360. The third gate insulating layer 323 may be disposed between the second portion 362 of the active cut 360 and the upper surfaces of third plurality of nanosheets NW3. The third gate insulating layer 323 may be disposed between the second portion 362 of the active cut 360 and the lower surfaces of the third plurality of nanosheets NW3.

For example, the third gate insulating layer 323 may not be disposed between the inner sidewalls of the third plurality of nanosheets NW3 and the second portion 362 of the active cut 360. The third gate insulating layer 323 may be in contact with the second portion 362 of the active cut 360, the third capping pattern 133, the third gate spacer 113, the first and second source/drain regions SD1 and SD2, the insulating pattern 101, and the third plurality of nanosheets NW3. The third gate insulating layer 323 may be in contact with parts of the sidewalls, in the first horizontal direction DR1, of a liner layer 170. For example, the third gate insulating layer 323 may include the same material as first and second gate insulating layers 121 and 122.

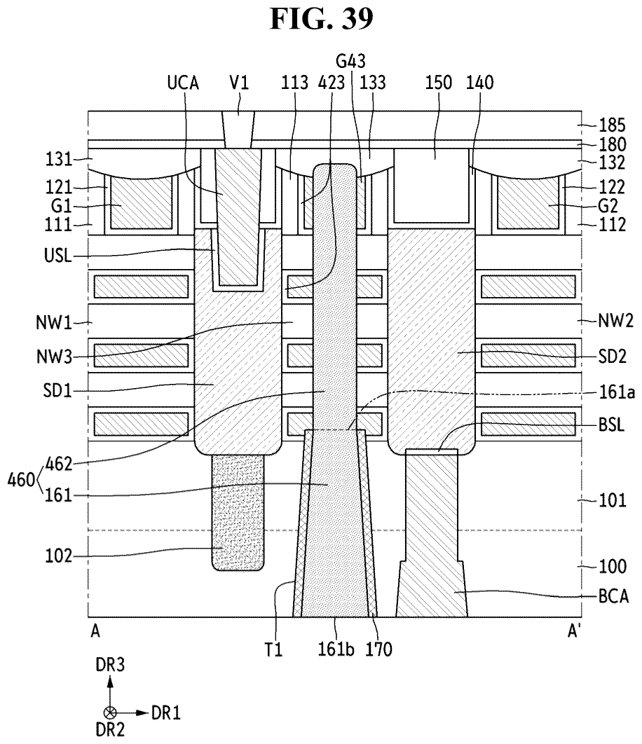

An example of a semiconductor device according to some embodiments of the present disclosure is described below with reference to FIG. 39, focusing mainly on the differences from the examples described above with reference to FIGS. 1 through 4.

FIG. 39 is a cross-sectional view illustrating a semiconductor device according to some embodiments of the present disclosure.

Referring to FIG. 39, in the semiconductor device according to some embodiments of the present disclosure, a third gate insulating layer 423 may be placed between an active cut 460 and third gate spacer 113. Additionally, a third gate electrode G43 may be disposed between a second portion 462 of the active cut 460 and the third gate insulating layer 423.

For example, the sidewalls, in the first horizontal direction DR1, of the second portion 462 of the active cut 460 may have a continuous slope profile. For example, the second portion 462 of the active cut 460 may extend up to the third capping pattern 133, penetrating a plurality of third plurality of nanosheets NW3, the third gate electrode G43, and the third gate insulating layer 423 in the vertical direction DR3.

For example, the third gate electrode G43 may be disposed on the sidewalls, in the first horizontal direction DR1, of the second portion 462 of the active cut 460 between the upper surface of the insulating pattern 101 and the lower surface of the lowermost nanosheet of the third plurality of nanosheets NW3. The third gate electrode G43 may be disposed on the sidewalls, in the first horizontal direction DR1, of the second portion 462 of the active cut 460 between adjacent nanosheets from among the third plurality of nanosheets NW3. The third gate electrode G43 may be disposed on the sidewalls, in the first horizontal direction DR1, of the second portion 462 of the active cut 460 above the upper surface of the uppermost nanosheet of the third plurality of nanosheets NW3. For example, the third gate electrode G43 may be in contact with the sidewalls, in the first horizontal direction DR1, of the second portion 462 of the active cut 460. For example, the upper surface of the third gate electrode G43 may be in contact with the lower surface of the third capping pattern 133. For example, the upper surface of the third gate electrode G43 may be formed lower than the upper surface of the second portion 462 of the active cut 460. For example, the third gate electrode G43 may include the same material as first and second gate electrodes G1 and G2.

For example, the third gate insulating layer 423 may be disposed between the third gate electrode G43 and the third gate spacer 113. The third gate insulating layer 423 may be disposed between the third gate electrode G43 and a first source/drain region SD1. The third gate insulating layer 423 may be disposed between the third gate electrode G43 and a second source/drain region SD2. The third gate insulating layer 423 may be disposed between the third gate electrode G43 and the upper surface of the insulating pattern 101. The third gate insulating layer 423 may be disposed between the third gate electrode G43 and the third plurality of nanosheets NW3.

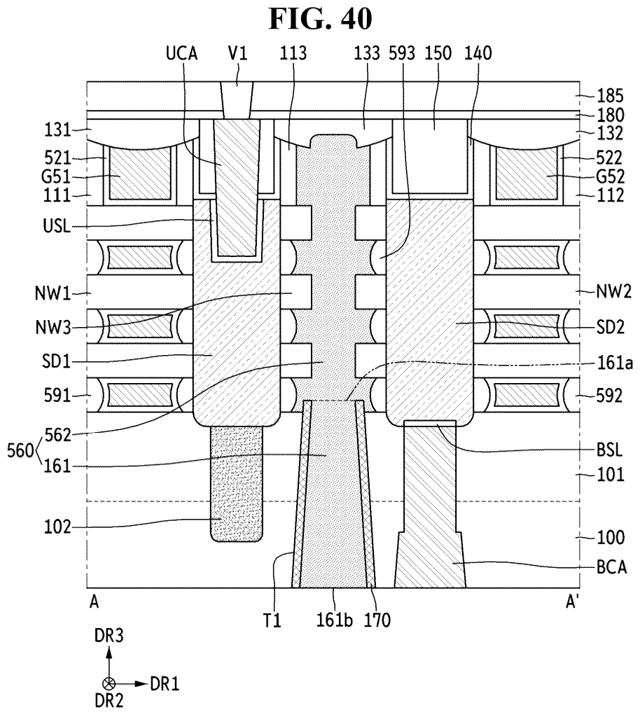

An example of semiconductor device according to some embodiments of the present disclosure is described below with reference to FIG. 40, focusing mainly on the differences from the examples described above with reference to FIGS. 1 through 4.

FIG. 40 is a cross-sectional view illustrating a semiconductor device according to some embodiments of the present disclosure.

Referring to FIG. 40, in the semiconductor device according to some embodiments of the present disclosure, a third internal spacer 593 may be disposed on both sidewalls, in the first horizontal direction DR1, of a second portion 562 of an active cut 560.

For example, a first internal spacer 591 may be disposed on the sidewalls, in the first horizontal direction DR1, of a first gate electrode G51 between the upper surface of an insulating pattern 101 and the lower surface of a lowermost nanosheet of the first plurality of nanosheets NW1. The first internal spacer 591 may be disposed between adjacent nanosheets from among the first plurality of nanosheets NW1 along the sidewalls in the first horizontal direction DR1 of the first gate electrode G51. For example, the first internal spacer 591 may be disposed between a first gate insulating layer 521 and a first source/drain region SD1. For example, the first internal spacer 591 may be in contact with the first gate insulating layer 521 and the first source/drain region SD1.

For example, a second internal spacer 592 may be positioned on the sidewalls, in the first horizontal direction DR1, of a second gate electrode G52 between the upper surface of the insulating pattern 101 and the lower surface of a lowermost nanosheet of the second plurality of nanosheets NW2. The second internal spacer 592 may be disposed between adjacent nanosheets from among the second plurality of nanosheets NW2 along the sidewalls, in the first horizontal direction DR1, of the second gate electrode G52. For example, the second internal spacer 592 may be disposed between a second gate insulating layer 522 and a second source/drain region SD2. For example, the second internal spacer 592 may be in contact with the second gate insulating layer 522 and the second source/drain region SD2.

For example, the third internal spacer 593 may be disposed on the sidewalls, in the first horizontal direction DR1, of the second portion 562 of the active cut 560 between the upper surface of the insulating pattern 101 and the lower surface of a lowermost nanosheet of the third plurality of nanosheets NW3. The third internal spacer 593 may be disposed between adjacent nanosheets from among the third plurality of nanosheets NW3 along the sidewalls, in the first horizontal direction DR1, of the second portion 562 of the active cut 560. For example, the third internal spacer 593 may be in contact with the second portion 562 of the active cut 560 and the first and second source/drain regions SD1 and SD2. The first internal spacer 591, the second internal spacer 592, and the third internal spacer 593 may include at least one of SiN, SiON, SiO₂, SiOCN, SiBN, SIOBN, SiOC, and a combination thereof.

While some embodiments are described herein with reference to the attached drawings in accordance with the technical spirit of the present disclosure, it should be understood that embodiments are not limited thereto. Embodiments may be manufactured in various different forms, and those of ordinary skill in the art will appreciate that the embodiments may be carried out in other specific forms without changing the scope of the disclosure. Therefore, the embodiments described above should be considered in all respects as illustrative and not restrictive.

What is claimed is:

1. A semiconductor device comprising:
a lower interlayer insulating layer;
an insulating pattern extending in a first horizontal direction on an upper surface of the lower interlayer insulating layer;
a plurality of nanosheets on the insulating pattern and spaced apart in a vertical direction;
an active cut comprising a first portion penetrating the lower interlayer insulating layer and the insulating pattern in the vertical direction, and a second portion separating the plurality of nanosheets in the first horizontal direction on an upper surface of the first portion, wherein a lower surface of the second portion is on an upper surface of the insulating pattern, and wherein the second portion is on inner sidewalls of the plurality of nanosheets in the first horizontal direction;
a first source/drain region on a first side of the active cut on the insulating pattern, wherein the first source/drain region is on first outer sidewalls of the plurality of nanosheets;
a second source/drain region on a second side of the active cut opposite to the first side of the active cut in the first horizontal direction on the insulating pattern, wherein the second source/drain region is on second outer sidewalls of the plurality of nanosheets; and
a bottom source/drain contact penetrating the lower interlayer insulating layer and the insulating pattern in the vertical direction, wherein the bottom source/drain contact is electrically connected to the second source/drain region, and wherein the bottom source/drain contact overlaps the first portion of the active cut in the first horizontal direction,
wherein a width of the upper surface of the first portion of the active cut in the first horizontal direction is smaller than a width of a lower surface of the first portion of the active cut in the first horizontal direction.

2. The semiconductor device of claim 1, further comprising:
a liner layer between the first portion of the active cut and each of the lower interlayer insulating layer and the insulating pattern, wherein the liner layer is on both sidewalls of the first portion of the active cut in the first horizontal direction.

3. The semiconductor device of claim 2, wherein an upper surface of the liner layer is on the second portion of the active cut.

4. The semiconductor device of claim 1, further comprising:
a capping pattern on an upper surface of the second portion of the active cut, wherein the capping pattern extends in a second horizontal direction different from the first horizontal direction.

5. The semiconductor device of claim 1, further comprising:
an upper source/drain contact above the first source/drain region, wherein the upper source/drain contact is electrically connected to the first source/drain region.

6. The semiconductor device of claim 5, wherein an upper surface of the upper source/drain contact is higher than an upper surface of the second portion of the active cut.

7. The semiconductor device of claim 1, wherein at least some of the second portion of the active cut overlaps the plurality of nanosheets in the vertical direction between adjacent nanosheets from among the plurality of nanosheets.

8. The semiconductor device of claim 1, wherein the second portion of the active cut is on an upper surface and a lower surface of each of the plurality of nanosheets.

9. The semiconductor device of claim 1, further comprising:
a gate spacer on both sidewalls of the second portion of the active cut in the first horizontal direction on an upper surface of an uppermost nanosheet from among the plurality of nanosheets, wherein the gate spacer is on the second portion of the active cut.

10. The semiconductor device of claim 1, further comprising:
a gate spacer on both sidewalls of the second portion of the active cut in the first horizontal direction on an upper surface of an uppermost nanosheet of the plurality of nanosheets; and
a gate insulating layer between the second portion of the active cut and the gate spacer.

11. The semiconductor device of claim 10, further comprising:
a gate electrode between the second portion of the active cut and the gate insulating layer, wherein the gate electrode is on the second portion of the active cut.

12. The semiconductor device of claim 1, further comprising:
an internal spacer between the second portion of the active cut and each of the first source/drain region and the second source/drain region between adjacent nanosheets from among the plurality of nanosheets.

13. A semiconductor device comprising:
a lower interlayer insulating layer;
an insulating pattern extending in a first horizontal direction on an upper surface of the lower interlayer insulating layer;
a first gate electrode extending in a second horizontal direction on the insulating pattern, wherein the second horizontal direction is different from the first horizontal direction;
a second gate electrode extending in the second horizontal direction on the insulating pattern, wherein the second gate electrode is spaced apart from the first gate electrode in the first horizontal direction;
an active cut comprising a first portion penetrating the lower interlayer insulating layer and the insulating pattern in a vertical direction, and a second portion on an upper surface of the first portion, wherein a lower surface of the second portion is on an upper surface of the insulating pattern;
a liner layer between the first portion of the active cut and each of the lower interlayer insulating layer and the insulating pattern, wherein the liner layer being is on both sidewalls of the first portion of the active cut in the first horizontal direction;
a first capping pattern on an upper surface of the first gate electrode, wherein the first capping pattern extends in the second horizontal direction;
a second capping pattern on an upper surface of the second gate electrode, wherein the second capping pattern extends in the second horizontal direction; and
a third capping pattern on an upper surface of the second portion of the active cut, wherein the third capping pattern extends in the second horizontal direction,
wherein upper surfaces of the first capping pattern, the second capping pattern, and the third capping pattern are on a same plane,
wherein the upper surface of the second portion of the active cut is lower than the upper surface of the third capping pattern, and
wherein a width of the upper surface of the first portion of the active cut in the first horizontal direction is smaller than a width of a lower surface of the first portion of the active cut in the first horizontal direction.

14. The semiconductor device of claim 13, further comprising:
a first source/drain region between the first gate electrode and the active cut on the insulating pattern;
a second source/drain region between the active cut and the second gate electrode on the insulating pattern; and
a bottom source/drain contact penetrating the lower interlayer insulating layer and the insulating pattern in the vertical direction,
wherein the bottom source/drain contact is electrically connected to the second source/drain region, and
wherein the bottom source/drain contact overlaps the first portion of the active cut in the first horizontal direction.

15. The semiconductor device of claim 14, wherein the bottom source/drain contact is spaced apart from the first portion of the active cut in the first horizontal direction.

16. The semiconductor device of claim 14, further comprising:
a sacrificial pattern below the first source/drain region within the insulating pattern, wherein the sacrificial pattern overlaps the first portion of the active cut in the first horizontal direction,
wherein the first portion of the active cut is spaced apart from the sacrificial pattern in the first horizontal direction.

17. The semiconductor device of claim 13, wherein at least some of a sidewall of the liner layer in the first horizontal direction is on the second portion of the active cut.

18. The semiconductor device of claim 13, wherein at least some of the second portion of the active cut overlaps the third capping pattern in the first horizontal direction.

19. The semiconductor device of claim 13, wherein the lower surface of the first portion of the active cut is on a same plane as a lower surface of the lower interlayer insulating layer.

20. A semiconductor device comprising:
a lower interlayer insulating layer;
an insulating pattern extending in a first horizontal direction on an upper surface of the lower interlayer insulating layer;
a plurality of nanosheets on the insulating pattern and spaced apart in a vertical direction;
a first gate electrode extending in a second horizontal direction on the insulating pattern, wherein the second horizontal direction is different from the first horizontal direction;
a second gate electrode extending in the second horizontal direction on the insulating pattern, wherein the second gate electrode is spaced apart from the first gate electrode in the first horizontal direction;
an active cut extending in the second horizontal direction between the first and second gate electrodes, wherein the active cut comprises a first portion penetrating the lower interlayer insulating layer and the insulating pattern in the vertical direction, and a second portion separating the plurality of nanosheets in the first horizontal direction on an upper surface of the first portion, wherein a lower surface of the second portion is on an upper surface of the insulating pattern, and wherein the second portion is on inner sidewalls of the plurality of nanosheets in the first horizontal direction;
a first source/drain region between the first gate electrode and the active cut, on the insulating pattern, wherein the first source/drain region is on first outer sidewalls of the plurality of nanosheets;
a second source/drain region between the active cut and the second gate electrode on the insulating pattern, wherein the second source/drain region is on second outer sidewalls of the plurality of nanosheets;
a liner layer between the first portion of the active cut and each of the lower interlayer insulating layer and the insulating pattern, wherein the liner layer is on both sidewalls of the first portion of the active cut in the first horizontal direction;
a capping pattern on an upper surface of the second portion of the active cut, wherein the capping pattern extends in the second horizontal direction;
a gate spacer on both sidewalls of the second portion of the active cut in the first horizontal direction on an upper surface of an uppermost nanosheet of the plurality of nanosheets, wherein the gate spacer is on the second portion of the active cut; and
a bottom source/drain contact penetrating the lower interlayer insulating layer and the insulating pattern in the vertical direction, wherein the bottom source/drain contact is electrically connected to the second source/drain region, and wherein the bottom source/drain contact overlaps the first portion of the active cut in the first horizontal direction,
wherein the upper surface of the second portion of the active cut is lower than an upper surface of the capping pattern,
wherein at least some of the second portion of the active cut overlaps the plurality of nanosheets in the vertical direction between adjacent nanosheets from among the plurality of nanosheets, and
wherein a width of the upper surface of the first portion of the active cut in the first horizontal direction is smaller than a width of a lower surface of the first portion of the active cut in the first horizontal direction.
